(19) United States
(12) Patent Application Publication
(10) Pub. No.: US 2011/0049542 A1
(43) Pub. Date: Mar. 3, 2011

(54) AlxGa(1-x)As Substrate, Epitaxial Wafer for Infrared LEDs, Infrared LED, Method of Manufacturing AlxGa(1-x)As Substrate, Method of Manufacturing Epitaxial Wafer for Infrared LEDs, and Method of Manufacturing Infrared LEDs

(75) Inventors: So Tanaka, Itami-shi (JP); Kenichi Miyahara, Itami-shi (JP); Hiroyuki Kitabayashi, Osaka-shi (JP); Koji Katayama, Itami-shi (JP); Tomonori Morishita, Itami-shi (JP); Tatsuya Moriwake, Itami-shi (JP)

(73) Assignee: SUMITOMO ELECTRIC INDUSTRIES, LTD., Osaka-shi (JP)

(21) Appl. No.: 12/935,913

(22) PCT Filed: May 27, 2009
(86) PCT No.: PCT/JP2009/059649

§ 371 Date: Oct. 1, 2010

(30) Foreign Application Priority Data
Jun. 3, 2008 (JP) 2008-146052
Mar. 6, 2009 (JP) 2009-053682
Apr. 22, 2009 (JP) 2009-104274

(51) Int. Cl. H01L 29/205; H01L 33/30; C30B 19/12

(52) U.S. Cl. 257/94; 257/183; 257/103; 117/54; 438/37; 257/E29.091; 257/E33.026; 257/E33.027

(57) ABSTRACT

The present invention makes available AlₓGa₍₁₋ₓ₎As (0≦x≦1) substrates, epitaxial wafers for infrared LEDs, infrared LEDs, methods of manufacturing AlₓGa₍₁₋ₓ₎As substrates, methods of manufacturing epitaxial wafers for infrared LEDs, and methods of manufacturing infrared LEDs, whereby a high level of transmissivity is maintained, and through which, in the fabrication of semiconductor devices, the devices prove to have superior characteristics.

An AlₓGa₍₁₋ₓ₎As substrate (10a) of the present invention is an AlₓGa₍₁₋ₓ₎As substrate (10a) furnished with an AlₓGa₍₁₋ₓ₎As layer (11) having a major surface (11a) and, on the reverse side from the major surface (11a), a rear face (11b), and is characterized in that in the AlₓGa₍₁₋ₓ₎As layer (11), the amount fraction x of Al in the rear face (11b) is greater than the amount fraction x of Al in the major surface (11a). In addition, the AlₓGa₍₁₋ₓ₎As substrate (10a) is further furnished with a GaAs substrate (13), contacting the rear face (11b) of the AlₓGa₍₁₋ₓ₎As layer (11).

### TECHNICAL FIELD

The present invention relates to AlₓGa₍₁₋ₓ₎As substrates, to epitaxial wafers for infrared LEDs, and to infrared LEDs, and to methods of manufacturing AlₓGa₍₁₋ₓ₎As substrates, methods of manufacturing epitaxial wafers for infrared LEDs, and methods of manufacturing infrared LEDs.

### BACKGROUND ART

LEDs (light-emitting diodes) exploiting AlₓGa₍₁₋ₓ₎As (0≦x≦1)—hereinafter also referred to as “AlGaAs” (aluminum gallium arsenide)—compound semiconductors are widely employed as infrared light sources. Infrared LEDs as infrared light sources are employed in such applications as optical communications and wireless transmission, wherein along with the scaling-up of transmitted data volume and the trend to longer-range transmission distances have come demands for improved output power from the infrared LEDs.

An example of a method of manufacturing such infrared LEDs is disclosed in Japanese Unexamined Pat. App. Pub. No. 2002-335008 (Patent Reference 1). The implementation of the following process steps is set forth in this Patent Reference 1. Specifically, to begin with an AlₓGa₍₁₋ₓ₎As support substrate is formed onto a GaAs (gallium arsenide) substrate by liquid-phase epitaxy (LPE). At that point, the amount fraction of Al (aluminum) in the AlₓGa₍₁₋ₓ₎As support substrate is approximately uniform. Subsequently, epitaxial layers are formed by organometallic vapor-phase epitaxy (OMVPE) or molecular beam epitaxy (MBE).

### Citation List

### Patent Literature

PTL 1: Japanese Unexamined Pat. App. Pub. No. 2002-335008

### SUMMARY OF INVENTION

### Technical Problem

In the above-noted Patent Reference 1, the amount fraction of Al in the AlₓGa₍₁₋ₓ₎As support substrate is for the most part uniform. As a result of dedicated research efforts, the present inventors discovered a problem with instances in which the Al amount fraction is high, in that the properties of infrared LEDs manufactured employing such AlₓGa₍₁₋ₓ₎As support substrates deteriorate. As a further result of their dedicated research efforts, the present inventors also discovered a problem with instances in which the Al amount fraction is low, in that the transmissivity of the AlₓGa₍₁₋ₓ₎As support substrates is poor.

Therein, an object of the present invention is to make available AlₓGa₍₁₋ₓ₎As substrates, epitaxial wafers for infrared LEDs, infrared LEDs, methods of manufacturing AlₓGa₍₁₋ₓ₎As substrates, methods of manufacturing epitaxial wafers for infrared LEDs, and methods of manufacturing infrared LEDs, whereby a high level of transmissivity is maintained, and through which, in the fabrication of semiconductor devices, the devices prove to have superior characteristics.

### Solution to Problem

As a result of their especially focused research efforts, the present inventors not only found that the properties of infrared LEDs manufactured employing the AlₓGa₍₁₋ₓ₎As support substrates are compromised when the Al amount fraction is high, but they also discovered the cause of the problem. Namely, aluminum has a propensity to oxidize readily, on account of which an oxide layer is liable to form on the surface of an AlₓGa₍₁₋ₓ₎As substrate. Since the oxide layer impairs epitaxial layers grown onto the AlₓGa₍₁₋ₓ₎As substrate, it proves to be a causative factor whereby defects are introduced into the epitaxial layers. The problem with defects introduced into epitaxial layers is that they are deleterious to the properties of infrared LEDs comprising the epitaxial layers.

Meanwhile, the present inventor's research efforts also led them to discover that the transmissivity of AlₓGa₍₁₋ₓ₎As substrates worsens the lower is the substrates' amount fraction of Al.

Therein, an AlₓGa₍₁₋ₓ₎As substrate of the present invention is an AlₓGa₍₁₋ₓ₎As substrate furnished with an AlₓGa₍₁₋ₓ₎As layer (0≦x≦1) having a major surface and, on the reverse side from the major surface, a rear face, and is characterized in that in the AlₓGa₍₁₋ₓ₎As layer, the amount fraction x of Al in the rear face is greater than the amount fraction x of Al in the major surface.

In the just-described AlₓGa₍₁₋ₓ₎As substrate, the AlₓGa₍₁₋ₓ₎As layer preferably contains a plurality of laminae, and the amount fraction x of Al in each of the plural laminae monotonically decreases heading from the plane of the layer's rear-face side to the plane of its major-surface side.

In the foregoing AlₓGa₍₁₋ₓ₎As substrate, letting ΔAl be the difference in amount fraction x of Al in two different points thickness-wise through the AlₓGa₍₁₋ₓ₎As layer, and letting Δt be the difference in thickness (μm) between the two points, then preferably ΔAl/Δt is greater than 0/μm.

In the just-described AlₓGa₍₁₋ₓ₎As substrate, preferably ΔAl/Δt is not greater than 6×10⁻²/μm.

In the above-described AlₓGa₍₁₋ₓ₎As substrate, preferably the amount fraction x of Al in the rear face of the AlₓGa₍₁₋ₓ₎As layer is not less than 0.12.

For the foregoing AlₓGa₍₁₋ₓ₎As substrate, a GaAs substrate preferably is further furnished, contacting the rear face of the AlₓGa₍₁₋ₓ₎As layer.

An epitaxial wafer of the present invention for infrared LEDs is furnished with an AlₓGa₍₁₋ₓ₎As substrate as set forth in any of the foregoing descriptions, and an epitaxial layer, formed onto the major surface of the AlₓGa₍₁₋ₓ₎As layer and including an active layer.

In the infrared-LED epitaxial wafer just described, preferably the amount fraction x of Al in the epitaxial layer plane of contact with the AlₓGa₍₁₋ₓ₎As layer is greater than the amount fraction x of Al in the AlₓGa₍₁₋ₓ₎As layer plane of contact with the epitaxial layer.

In the foregoing epitaxial wafer for infrared LEDs, preferably the epitaxial layer further includes a buffer layer having a plane of contact with the AlₓGa₍₁₋ₓ₎As layer, and the amount fraction x of Al in the buffer layer is lower than the amount fraction x of Al in the active layer.

In the above-described infrared-LED epitaxial wafer, preferably the epitaxial layer further includes a buffer layer having a plane of contact with the AlₓGa₍₁₋ₓ₎As layer, and the amount fraction x of Al in the buffer layer is lower than the amount fraction x of Al in the AlₓGa₍₁₋ₓ₎As layer plane of contact with the epitaxial layer, and lower than the amount fraction x of Al in the active layer.

In the foregoing epitaxial wafer for infrared LEDs, preferably the peak concentration of oxygen in the major surface of the AlₓGa₍₁₋ₓ₎As layer is not greater than 5×10²⁰ atoms/cm³.

In the foregoing infrared-LED epitaxial wafer, preferably the planar density of oxygen in the major surface of the AlₓGa₍₁₋ₓ₎As layer is not greater than 2.5×10¹⁵ atoms/cm².

An infrared LED of the present invention is furnished with: an AlₓGa₍₁₋ₓ₎As substrate as set forth in any of the foregoing descriptions; an epitaxial layer; a first electrode; and a second electrode. The epitaxial layer is formed onto the major surface of the AlₓGa₍₁₋ₓ₎As layer, and includes an active layer. The first electrode is formed on the surface of the epitaxial layer. The second electrode is formed on the rear face of the AlₓGa₍₁₋ₓ₎As layer. In AlₓGa₍₁₋ₓ₎As substrates of a form furnished with a GaAs substrate, the second electrode may be formed on the rear face of the GaAs substrate.

An AlₓGa₍₁₋ₓ₎As substrate manufacturing method of the present invention is provided with a step of preparing a GaAs substrate, and a step of growing, by liquid-phase epitaxy, onto the GaAs substrate an AlₓGa₍₁₋ₓ₎As layer (0≦x≦1) having a major surface and, on the reverse side from the major surface, a rear face. Then, in the step of growing an AlₓGa₍₁₋ₓ₎As layer, the method is characterized in that the AlₓGa₍₁₋ₓ₎As layer is grown with the amount fraction x of Al in the rear face being greater than the amount fraction x of Al in the major surface.

With the AlₓGa₍₁₋ₓ₎As substrate manufacturing method, in the AlₓGa₍₁₋ₓ₎As layer growing step, preferably the AlₓGa₍₁₋ₓ₎As layer is grown containing a plurality of laminae in which the amount fraction x of Al monotonically decreases heading from the plane of the layer's rear-face side to the plane of its major-surface side.

In the foregoing AlₓGa₍₁₋ₓ₎As substrate manufacturing method, letting ΔAl be the difference in amount fraction x of Al in two different points thickness-wise through the AlₓGa₍₁₋ₓ₎As layer, and letting Δt be the difference in thickness (μm) between the two points, then preferably ΔAl/Δt is greater than 0/μm.

In the just-described AlₓGa₍₁₋ₓ₎As substrate manufacturing method, preferably ΔAl/Δt is not greater than 6×10⁻²/μm.

In the above-described AlₓGa₍₁₋ₓ₎As substrate manufacturing method, preferably the amount fraction x of Al in the rear face of the AlₓGa₍₁₋ₓ₎As layer is not less than 0.12.

With the foregoing AlₓGa₍₁₋ₓ₎As substrate manufacturing method, preferably a step of removing the GaAs substrate may be further provided.

A method of the present invention of manufacturing an epitaxial wafer for infrared LEDs is provided with: a step of manufacturing an AlₓGa₍₁₋ₓ₎As substrate by an AlₓGa₍₁₋ₓ₎As substrate manufacturing method set forth in any of the foregoing descriptions; and a step of forming onto the major surface of the AlₓGa₍₁₋ₓ₎As layer, by at least either OMVPE or MBE, or else by a combination of the two techniques, an epitaxial layer containing an active layer.

In the infrared-LED epitaxial wafer manufacturing method just described, preferably the amount fraction x of Al in the epitaxial layer plane of contact with the AlₓGa₍₁₋ₓ₎As layer is greater than the amount fraction x of Al in the AlₓGa₍₁₋ₓ₎As layer plane of contact with the epitaxial layer.

In the foregoing method of manufacturing an epitaxial wafer for infrared LEDs, in the step of forming an epitaxial layer, preferably the epitaxial layer is formed further including a buffer layer having a plane of contact with the AlₓGa₍₁₋ₓ₎As layer, with the amount fraction x of Al in the buffer layer being lower than the amount fraction x of Al in the active layer.

In the above-described infrared-LED epitaxial wafer manufacturing method, in the step of forming an epitaxial layer, preferably the epitaxial layer is formed further including a buffer layer having a plane of contact with the AlₓGa₍₁₋ₓ₎As layer, and the amount fraction x of Al in the buffer layer is lower than the amount fraction x of Al in the AlₓGa₍₁₋ₓ₎As layer plane of contact with the epitaxial layer, and lower than the amount fraction x of Al in the active layer.

In the foregoing method of manufacturing an epitaxial wafer for infrared LEDs, preferably the peak concentration of oxygen in the major surface of the AlₓGa₍₁₋ₓ₎As layer is not greater than 5×10²⁰ atoms/cm³.

In the foregoing infrared-LED epitaxial wafer manufacturing method, preferably the planar density of oxygen in the major surface of the AlₓGa₍₁₋ₓ₎As layer is not greater than 2.5×10¹⁵ atoms/cm².

A method of the present invention of manufacturing an infrared LED is furnished with: a step of manufacturing an AlₓGa₍₁₋ₓ₎As substrate by an AlₓGa₍₁₋ₓ₎As substrate manufacturing method as set forth in any of the foregoing descriptions; a step of forming onto the major surface of the AlₓGa₍₁₋ₓ₎As layer, by either OMVPE or MBE, an epitaxial layer containing an active layer, to yield an epitaxial wafer; a step of forming a first electrode on the surface of the epitaxial wafer; and a step of forming a second electrode on either the rear face of the AlₓGa₍₁₋ₓ₎As layer, or the rear face of the GaAs substrate (in AlₓGa₍₁₋ₓ₎As substrates of a form furnished with a GaAs substrate).

### Advantageous Effects of Invention

AlₓGa₍₁₋ₓ₎As substrates, epitaxial wafers for infrared LEDs, infrared LEDs, methods of manufacturing AlₓGa₍₁₋ₓ₎As substrates, methods of manufacturing epitaxial wafers for infrared LEDs, and methods of manufacturing infrared LEDs of the present invention maintain a high level of transmissivity and, in the fabrication of semiconductor devices, allow the devices to have superior characteristics.

### BRIEF DESCRIPTION OF DRAWINGS

FIG. 1 is a sectional diagram illustratively outlining an AlₓGa₍₁₋ₓ₎As substrate in Embodying Mode 1 of the present invention.

FIG. 2 is a chart for explaining the amount fraction x of Al in an AlₓGa₍₁₋ₓ₎As layer in Embodying Mode 1 of the present invention.

FIG. 3 is a chart for explaining the amount fraction x of Al in an AlₓGa₍₁₋ₓ₎As layer in Embodying Mode 1 of the present invention.

FIG. 4 is a chart for explaining the amount fraction x of Al in an AlₓGa₍₁₋ₓ₎As layer in Embodying Mode 1 of the present invention.

FIGS. 5(A) through (G) are charts for explaining the amount fraction x of Al in an AlₓGa₍₁₋ₓ₎As layer in Embodying Mode 1 of the present invention.

FIG. 6 is a flowchart representing a method of manufacturing an AlₓGa₍₁₋ₓ₎As substrate in Embodying Mode 1 of the present invention.

FIG. 7 is a sectional diagram illustratively outlining a GaAs substrate in Embodying Mode 1 of the present invention.

FIG. 8 is a sectional diagram illustratively outlining an as-grown AlₓGa₍₁₋ₓ₎As layer in Embodying Mode 1 of the present invention.

FIGS. 9(A) through (C) are charts for explaining the effect, in Embodying Mode 1 of the present invention, of furnishing an AlₓGa₍₁₋ₓ₎As layer with a plurality of lamina in which the amount fraction x of Al monotonically decreases.

FIG. 10 is a sectional diagram illustratively outlining an AlₓGa₍₁₋ₓ₎As substrate in Embodying Mode 2 of the present invention.

FIG. 11 is a flowchart representing a method of manufacturing an AlₓGa₍₁₋ₓ₎As substrate in Embodying Mode 2 of the present invention.

FIG. 12 is a sectional diagram illustratively outlining an infrared-LED epitaxial wafer in Embodying Mode 3 of the present invention.

FIG. 13 is an enlarged sectional diagram illustratively outlining an active layer in Embodying Mode 3 of the present invention.

FIG. 14 is a flowchart representing a method of manufacturing an infrared-LED epitaxial wafer in Embodying Mode 3 of the present invention.

FIG. 15 is a sectional diagram illustratively outlining an infrared-LED epitaxial wafer in Embodying Mode 4 of the present invention.

FIG. 16 is a flowchart representing a method of manufacturing an epitaxial wafer in Embodying Mode 4 of the present invention.

FIG. 17 is a sectional diagram illustratively outlining an infrared-LED epitaxial wafer in Embodying Mode 5 of the present invention.

FIG. 18 is a sectional diagram illustratively outlining an infrared LED in Embodying Mode 6 of the present invention.

FIG. 19 is a flowchart representing a method of manufacturing an infrared LED in Embodying Mode 6 of the present invention.

FIG. 20 is a sectional diagram illustratively outlining an infrared LED in Embodying Mode 7 of the present invention.

FIG. 21 is a graph plotting transmissivity versus amount fraction x of Al in AlₓGa₍₁₋ₓ₎As layers of Embodiment 1.

FIG. 22 is a graph plotting surface oxygen quantity versus amount fraction x of Al in AlₓGa₍₁₋ₓ₎As layers of Embodiment 1.

FIG. 23 is a sectional diagram illustratively outlining an infrared-LED epitaxial wafer in Embodiment 3.

FIG. 24 is a chart diagramming light output, in Embodiment 3, from an infrared-LED epitaxial wafer furnished with an active layer having multiquantum-well structures, and from an epitaxial wafer for double-heterostructure infrared LEDs.

FIG. 25 is a sectional diagram illustratively outlining an infrared-LED epitaxial wafer in Embodiment 4.

FIG. 26 is a chart diagramming the relationship between window-layer thickness and light output power in Embodiment 4.

FIG. 27 is a sectional diagram illustratively outlining an infrared LED epitaxial wafer in a modified example of Embodying Mode 4 of the present invention.

FIG. 28 is a sectional diagram illustratively outlining an infrared LED in a modified example of Embodying Mode 6 of the present invention.

FIG. 29 is a sectional diagram illustratively outlining an infrared LED in a modified example of Embodying Mode 7 of the present invention.

FIG. 30 is a chart plotting the relationship, in Embodiment 6, between thickness and amount fraction of Al in Samples 3 and 4.

FIG. 31 is a chart plotting the relationship, in Embodiment 6, between thickness and amount fraction of Al in Sample 5.

FIG. 32 is a chart plotting the relationship between thickness and ΔAl/Δt in Samples 3 and 4 of Embodiment 6.

FIG. 33 is a chart plotting the relationship between thickness and ΔAl/Δt in Sample 5 of Embodiment 6.

FIG. 34 is a chart plotting the relationship, in Embodiment 6, between ΔAl/Δt and output power for Al amount fractions of from 0 to less than 0.3.

FIG. 35 is a chart plotting the relationship, in Embodiment 6, between ΔAl/Δt and output power for Al amount fractions of from 0.3 to less than 0.5.

FIG. 36 is a chart plotting the relationship, in Embodiment 6, between ΔAl/Δt and output power for Al amount fractions of from 0.5 to 1.0.

FIG. 37 is a sectional chart plotting the relationships of oxygen concentration and secondary-ion intensity to thickness in epitaxial wafers of Embodiment 7.

FIG. 38 is a chart plotting the relationship between oxygen peak concentration in the major surface of, and output power from, AlₓGa₍₁₋ₓ₎As layers in Embodiment 7.

FIG. 39 is a chart plotting the relationship between planar oxygen density in the major surface of, and output power from, AlₓGa₍₁₋ₓ₎As layers in Embodiment 7.

FIG. 40 is a chart plotting forward voltages for Samples 6 through 9 in Embodiment 8.

FIG. 41 is a chart plotting results of measuring the emission wavelength from an infrared LED in Embodiment 10.

### DESCRIPTION OF EMBODIMENTS

In the following, an explanation based on the drawings will be made of modes of embodying the present invention.

### Embodying Mode 1

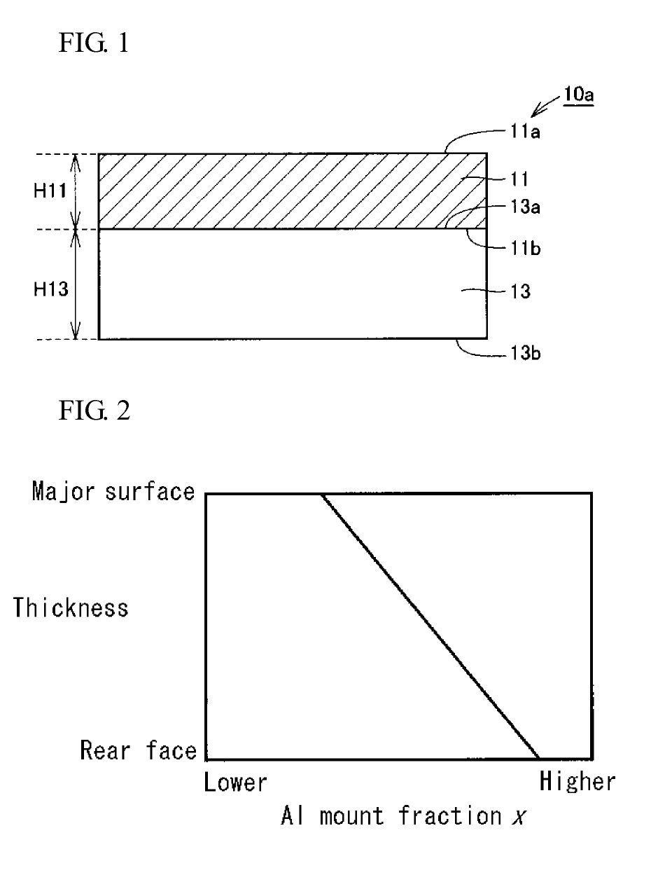

To begin with, referring to FIG. 1, an explanation of an AlₓGa₍₁₋ₓ₎As substrate in the present embodying mode will be made.

As represented in FIG. 1, an AlₓGa₍₁₋ₓ₎As substrate 10a is furnished with a GaAs substrate 13, and an AlₓGa₍₁₋ₓ₎As layer 11 formed onto the GaAs substrate 13.

The GaAs substrate 13 has a major surface 13a, and a rear face 13b on the reverse side from the major surface 13a. The AlₓGa₍₁₋ₓ₎As layer 11 has a major surface 11a, and a rear face 11b on the reverse side from the major surface 11a.

The GaAs substrate 13 may or may not be misoriented—for example, it may have a major surface 13a that is a {100} plane, or that is tilted more than 0° but 15.8° or less from a {100} plane. It is preferable that the GaAs substrate 13 have a major surface 13a that is a {100} plane, or that is tilted more than 0° but 2° or less from a {100} plane. It is further preferable that the GaAs substrate 13 have a surface that is a {100} plane, or that is tilted more than 0° but 0.2° or less from a {100} plane. The GaAs substrate 13 surface may be a specular surface, or may be a rough surface. (It will be understood that the braces “{ }” indicate a family of planes.)

The AlₓGa₍₁₋ₓ₎As layer 11 has a major surface 11a and, on the reverse side from the major surface 11a, a rear face 11b. The major surface 11a is the surface on the reverse side from the surface that contacts the GaAs substrate 13. The rear face 11b is the surface that contacts the GaAs substrate 13.

The AlₓGa₍₁₋ₓ₎As layer 11 is formed so as to contact on the major surface 13a of the GaAs substrate 13. Put differently, the GaAs substrate 13 is formed as to contact on the rear face 11b of the AlₓGa₍₁₋ₓ₎As layer 11.

In the AlₓGa₍₁₋ₓ₎As layer 11, the amount fraction x of Al in the rear face 11b is greater than the amount fraction x of Al in the major surface 11a. It should be understood that the amount fraction x is the mole fraction of Al, while the amount fraction (1-x) is the mole fraction of Ga.

Therein, the mole fractions in the AlₓGa₍₁₋ₓ₎As layer 11 will be explained with reference to FIGS. 2 through 5.

In FIGS. 2 through 5, the vertical axis indicates position thickness-wise traversing from the rear face to the major surface of the AlₓGa₍₁₋ₓ₎As layer 11, while the horizontal axis represents the Al amount fraction x in each position.

As shown in FIG. 2, with the AlₓGa₍₁₋ₓ₎As layer 11, traversing from the rear face 11b to the major surface 11a, the amount fraction x of Al monotonically decreases. “Monotonically decreases” means that heading from the rear face 11b to the major surface 11a of the AlₓGa₍₁₋ₓ₎As layer 11 (heading in the growth direction), the amount fraction x is constantly the same or decreasing, and that, compared with the rear face 11b, the major surface 11a is where the amount fraction x is lower.

Put differently, “monotonically decreases” would not include a section in which the amount fraction x increases heading in the growth direction.

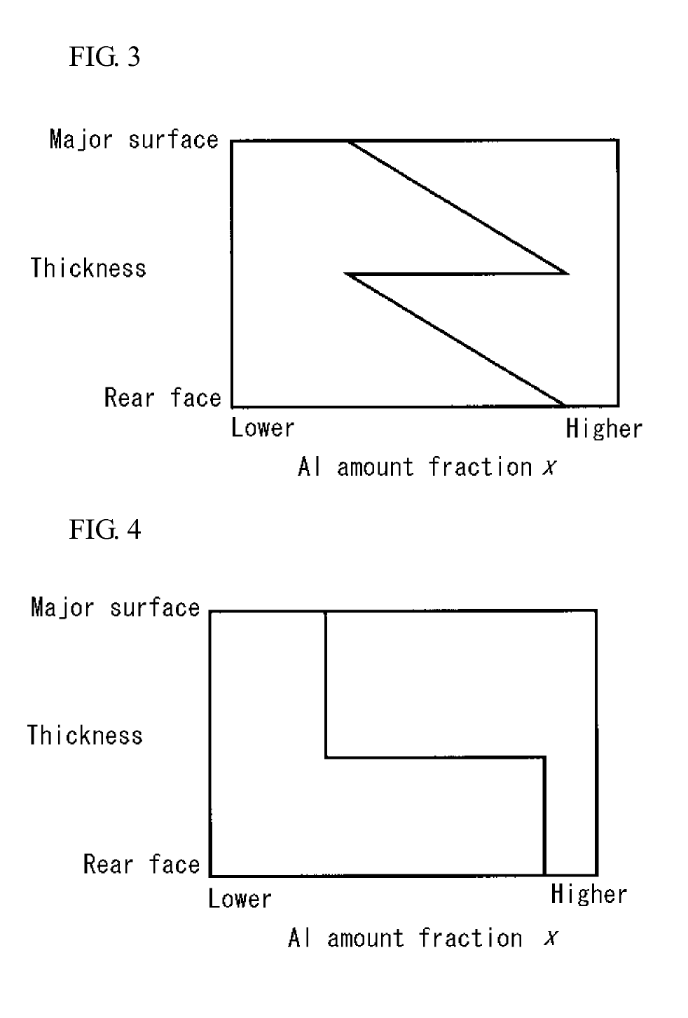

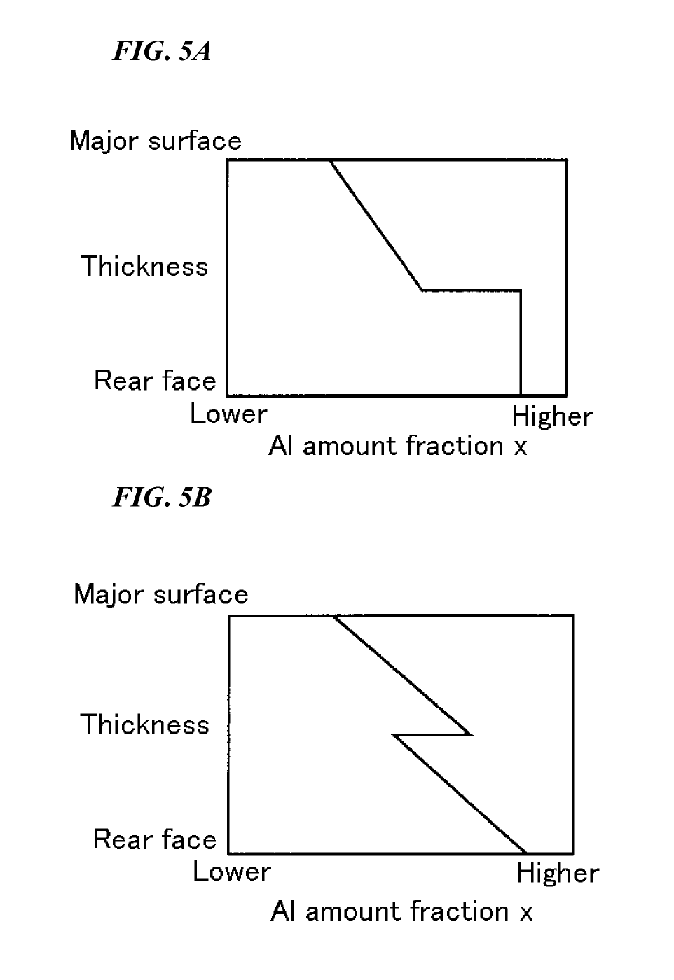

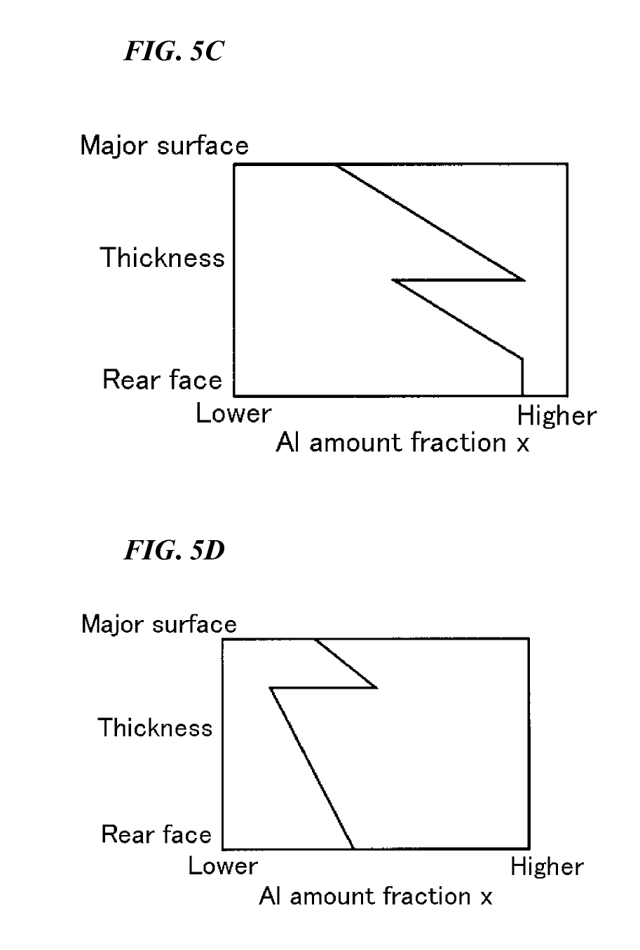

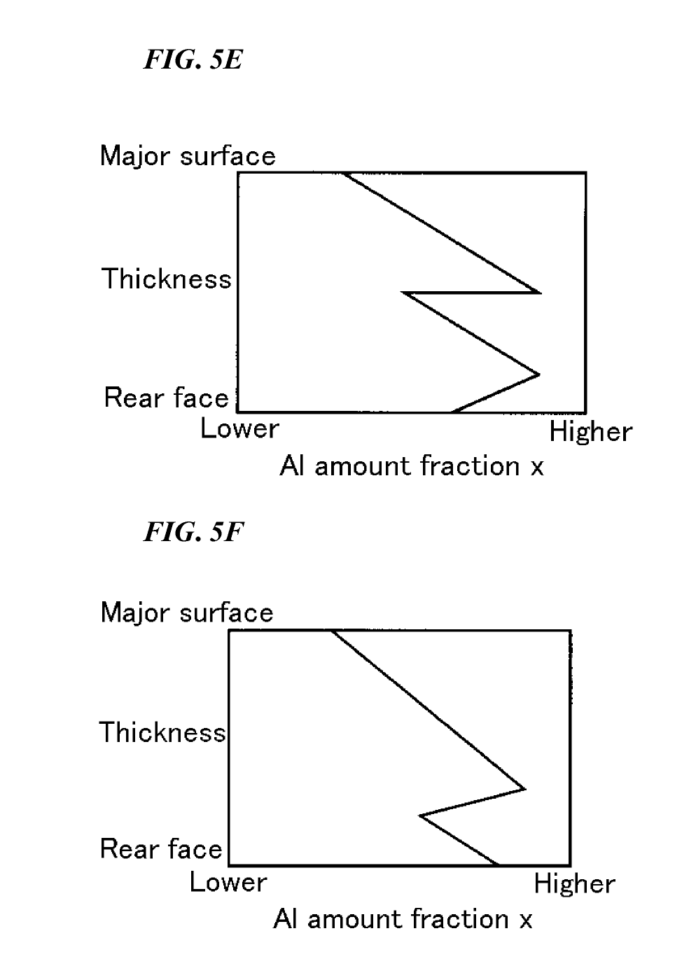

As indicated in FIGS. 3 through 5, the AlₓGa₍₁₋ₓ₎As layer 11 may include a plurality of laminae (in FIGS. 3 through 5, it includes two laminae). With the AlₓGa₍₁₋ₓ₎As layer 11 represented in FIG. 3, traversing in each lamina from the rear face 11b side to the major surface 11a side, the amount fraction x of Al monotonically decreases. Meanwhile, with the AlₓGa₍₁₋ₓ₎As layer 11 represented in FIG. 4, the amount fraction x of Al is uniform in each lamina, but the amount fraction x of Al in the lamina along the rear face 11b is greater than in that along the major surface 11a. On the other hand, the amount fraction x of Al in the lamina along the rear face 11b of the AlₓGa₍₁₋ₓ₎As layer 11 represented in FIG. 5A is uniform, while the amount fraction x of Al in the lamina along the major surface 11a monotonically decreases, with the Al amount fraction x in the lamina along the rear face 11b being greater than the Al amount fraction x along the major surface 11a. In sum, with the AlₓGa₍₁₋ₓ₎As layers 11 represented in FIGS. 4 and 5A, as a whole, the amount fraction x of Al monotonically decreases.

It should be understood that the amount fraction x of Al in the AlₓGa₍₁₋ₓ₎As layer 11 is not limited to the foregoing, and the composition may be as indicated for example in FIGS. 5B-5G, or may be other examples as well. Also, the AlₓGa₍₁₋ₓ₎As layer 11 is not limited to the above-described implementations containing one lamina or two laminae, but may contain three or more laminae, as long as the amount fraction x of Al in the rear face 11b is greater than the amount fraction x of Al in the major surface 11a.

When the AlₓGa₍₁₋ₓ₎As substrate 10a is utilized in an LED, the AlₓGa₍₁₋ₓ₎As layer 11 assumes the role of, for example, a window layer that diffuses current and that transmits light from the active layer.

It is also preferable that, letting ΔAl be the difference in amount fraction x of Al in two different points thickness-wise through the AlₓGa₍₁₋ₓ₎As layer 11, and letting Δt be the difference in thickness (μm) between the two points, ΔAl/Δt be greater than 0/μm. While larger ΔAl/Δt values are the more preferable, for manufacturing reasons, the upper limit is, for example, not greater than 6×10⁻²/μm, more preferably not greater than 3×10⁻²/μm.

ΔAl/Δt is obtained by measuring ΔAl at 1-μm increments, for example, traversing the AlₓGa₍₁₋ₓ₎As layer 11 from the major surface 11a to the rear face 11b, with an electron probe microanalyzer (EPMA) and an SIMS. ΔAl/Δt can be measured at arbitrary positions in the AlₓGa₍₁₋ₓ₎As layer 11.

It is additionally preferable that the amount fraction x of Al in the rear face 11b of the AlₓGa₍₁₋ₓ₎As layer 11 be not less than 0.12.

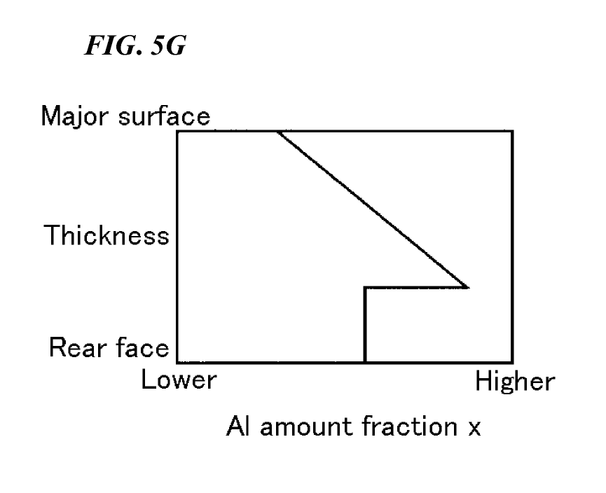

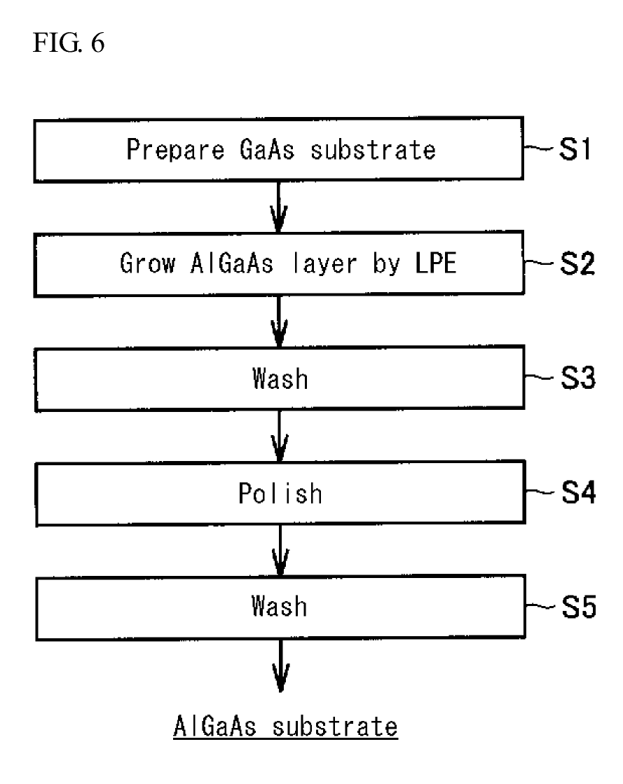

To continue: With reference to FIG. 6, an explanation of a method of manufacturing an AlₓGa₍₁₋ₓ₎As substrate in the present embodying mode will be made.

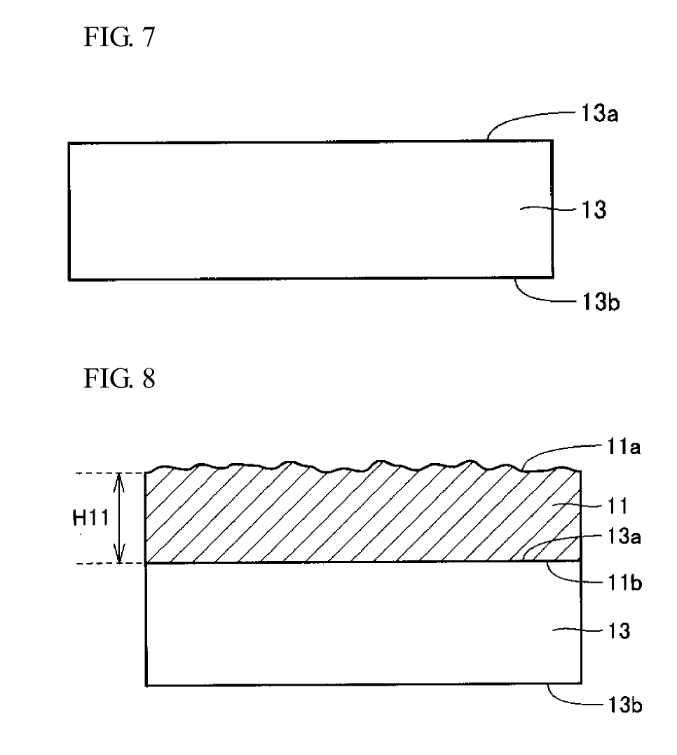

As indicated in FIGS. 6 and 7, initially a GaAs substrate 13 is prepared (Step S1).

The GaAs substrate 13 may or may not be misoriented—for example, it may have a major surface 13a that is a {100} plane, or that is tilted more than 0° but not more than 15.8° from a {100} plane. It is preferable that the GaAs substrate 13 have a major surface 13a that is a {100} plane, or that is tilted more than 0° but not more than 2° from a {100} plane. It is further preferable that the GaAs substrate 13 have a major surface 13a that is a {100} plane, or that is tilted more than 0° but not more than 0.2° from a {100} plane.

As indicated in FIGS. 6 and 8, next an AlₓGa₍₁₋ₓ₎As layer (0≦x≦1) 11 having a major surface 11a is grown by LPE onto the GaAs substrate 13 (Step S2).

By Step S2 of growing the AlₓGa₍₁₋ₓ₎As layer 11, an AlₓGa₍₁₋ₓ₎As layer 11 in which the amount fraction x of Al in the layer's interface with the GaAs substrate 13 (the rear face 11b) is greater than the amount fraction x of Al in the major surface 11a is grown. And it is preferable that an AlₓGa₍₁₋ₓ₎As layer 11 in which the amount fraction x of Al in the rear face 11b is 0.12 or more be grown.

The LPE technique is not particularly limited; a slow-cooling or temperature-profile technique can be employed. It should be understood that “LPE” refers to a method of growing AlₓGa₍₁₋ₓ₎As (0≦x≦1) crystal from the liquid phase. A “slow-cooling” technique is a method of gradually lowering the temperature of a source-material solution to grow AlₓGa₍₁₋ₓ₎As crystal. A “temperature-profile” technique refers to a method of setting up a temperature gradient in a source-material solution to grow AlₓGa₍₁₋ₓ₎As crystal.

When a lamina with a fixed amount fraction x of Al in the AlₓGa₍₁₋ₓ₎As layer 11 is to be grown, temperature-profile and slow-cooling techniques are preferably utilized, while when a lamina in which the amount fraction x of Al decreases heading upward (in the growth direction) is to be grown, slow-cooling is preferably utilized. Utilizing slow cooling is particularly preferable, because of its advantages in terms of volume produciblity and low cost. These techniques also may be combined.

With LPE, since a chemical equilibrium between the liquid and solid phases is exploited, the growth rate is rapid. On that account, an AlₓGa₍₁₋ₓ₎As layer 11 of considerable thickness may be readily formed. Specifically, an AlₓGa₍₁₋ₓ₎As layer 11 having a height H11 preferably of from 10 μm to 1000 μm, more preferably from 20 μm to 140 μm is grown. (The height H11 in this case is the minimum thickness along the AlₓGa₍₁₋ₓ₎As layer 11 thickness-wise.)

A further preferable condition is that the ratio of the height H11 of the AlₓGa₍₁₋ₓ₎As layer 11 to the height H13 of the GaAs substrate 13 (H11/H13) be, for example, from 0.1 to 0.5, more preferably from 0.3 to 0.5. This conditional factor makes it possible to mitigate the incidence of warp in the AlₓGa₍₁₋ₓ₎As layer 11 having been grown onto the GaAs substrate 13.

Furthermore, the AlₓGa₍₁₋ₓ₎As layer 11 may be grown so as to incorporate p-type dopants such as zinc (Zn), magnesium (Mg) and carbon (C), and n-type dopants such as selenium (Se), sulfur (S) and tellurium (Te), for example.

In this way growing an AlₓGa₍₁₋ₓ₎As layer 11 by LPE produces a jaggedness in the major surface 11a of the AlₓGa₍₁₋ₓ₎As layer 11, as indicated in FIG. 8.

Next, the major surface 11a of the AlₓGa₍₁₋ₓ₎As layer 11 is washed (Step S3). In Step S3, washing is preferably done using an alkali solution. However, an oxidizing solution such as phosphoric acid or sulfuric acid may also be employed. The alkali solution preferably contains ammonia and hydrogen peroxide. Washing the major surface 11a with an alkali solution containing ammonia and hydrogen peroxide etches the surface, whereby impurities clinging to the major surface 11a from having been in contact with air may be removed. By controlling the process so that, for example, with an etching rate of 0.2 μm/min or less, not more than 0.2 μm is etched from the major surface 11a side, impurities on the major surface 11a are reduced and at the same time the extent of etching will be slight. It should be noted that Step S3 of washing the major surface 11a may be omitted.

Next, the GaAs substrate 13 and the AlₓGa₍₁₋ₓ₎As layer 11 are dried with alcohol. This step of drying may be omitted, however.

Next, the major surface 11a of the AlₓGa₍₁₋ₓ₎As layer 11 is polished (Step S4). The method of polishing is not particularly limited; mechanical polishing, chemical-mechanical polishing, electrolytic polishing, or chemical polishing techniques may be employed, while in terms of polishing ease, mechanical polishing or chemical polishing are preferable.

The major surface 11a is polished so that the RMS roughness of the major surface 11a will be, for example, 0.05 nm or less. The RMS surface roughness is preferably minimal. Here, “RMS surface roughness” signifies a surface's mean-square roughness, as defined by JIS BO601—that is, the square root of the averaged value of the squares of the distance (deviation) from an averaging plane to a measuring plane. It should be noted that this polishing Step S4 may be omitted.

Next, the major surface 11a of the AlₓGa₍₁₋ₓ₎As layer 11 is washed (Step S5). Inasmuch as this Step 5 of washing the major surface 11a is the same as Step 3 of washing the major surface 11a prior to implementing polishing Step 4, explanation of the step will not be repeated. It should be noted that this washing Step S5 may be omitted.

Next, the GaAs substrate 13 and the AlₓGa₍₁₋ₓ₎As layer 11 are, prior to epitaxial growth utilizing the AlₓGa₍₁₋ₓ₎As substrate 10a, thermally cleaned in an H₂ (hydrogen) and AsH₃ (arsine) flow. It should be understood that this thermal cleaning step may be omitted.

Implementing the foregoing Steps S1 through S5 enables the manufacture of an AlₓGa₍₁₋ₓ₎As substrate 10a in the present embodying mode, represented in FIG. 1.

As described in the foregoing, an AlₓGa₍₁₋ₓ₎As substrate 10a in the present embodying mode is an AlₓGa₍₁₋ₓ₎As substrate 10a furnished with an AlₓGa₍₁₋ₓ₎As layer 11 having a major surface 11a and, on the reverse side from the major surface 11a, a rear face 11b, and is characterized in that in the AlₓGa₍₁₋ₓ₎As layer 11, the amount fraction x of Al in the rear face 11b is greater than the amount fraction x of Al in the major surface 11a. A GaAs substrate 13 contacting the rear face 11b of the AlₓGa₍₁₋ₓ₎As layer 11 is then further provided.

In addition, a method of manufacturing an AlₓGa₍₁₋ₓ₎As substrate 10a in the present embodying mode is provided with a step (Step S1) of preparing a GaAs substrate 13, and a step (Step S2) of growing, by LPE, an AlₓGa₍₁₋ₓ₎As layer 11 having a major surface 11a onto the GaAs substrate 13. The method is characterized in that in the step of growing the AlₓGa₍₁₋ₓ₎As layer 11 (Step S2), an AlₓGa₍₁₋ₓ₎As layer 11 is grown in which the amount fraction x of Al in the interface between the layer and the GaAs substrate 13 (in the rear face 11b) is greater than the amount fraction x of Al in the major surface 11a.

According to an AlₓGa₍₁₋ₓ₎As substrate 10a and a method of manufacturing an AlₓGa₍₁₋ₓ₎As substrate 10a in the present embodying mode, the amount fraction x of Al in the rear face 11b is greater than the amount fraction x of Al in the major surface 11a. The presence of aluminum, which has a propensity to oxidize, on the major surface 11a may therefore be kept to a minimum. And the formation of an oxide layer, which would act as an insulator, on the surface of the AlₓGa₍₁₋ₓ₎As substrate 10a (the major surface 11a of the AlₓGa₍₁₋ₓ₎As layer 11 in the present embodying mode) may therefore be restrained.

Especially since the AlₓGa₍₁₋ₓ₎As layer 11 is grown by LPE, oxygen is unlikely to be taken into the layer-internal region, apart from the major surface 11a. Accordingly, when epitaxial layers are grown onto the AlₓGa₍₁₋ₓ₎As substrate 10a, defects can be kept from being introduced into the epitaxial layers. The characteristics of an infrared LED furnished with the epitaxial layers can be improved as a result.

Again, the Al amount fraction x in the major surface 11a is less than the Al amount fraction x in the rear face 11b. The present inventor's intensive research efforts led them to discover that the greater the Al amount fraction x is, the better will the transmissivity of the AlₓGa₍₁₋ₓ₎As substrate 10a be. And even if the layer contains much aluminum along the rear face 11b, because the period of time it is exposed on the surface is short, formation of any oxide layer may be minimized. Therefore, growing AlₓGa₍₁₋ₓ₎As crystal of higher Al amount fraction x, with a portion where oxide-layer formation is minimized, allows the transmissivity to be improved.

In this way, in the AlₓGa₍₁₋ₓ₎As layer 11, the amount fraction x of Al along the major surface 11a is made lower so as to improve the device characteristics, while the amount fraction x of Al along the rear face 11b is made higher so as to improve the transmissivity. Hence, an AlₓGa₍₁₋ₓ₎As substrate 10a can be realized whereby a high level of transparency is maintained, and with which, when devices are fabricated, the devices prove to have superior characteristics.

In the AlₓGa₍₁₋ₓ₎As substrate 10a described above, preferably, as indicated in FIG. 3, the AlₓGa₍₁₋ₓ₎As layer 11 contains a plurality of laminae, and the Al amount fraction x in each lamina monotonically decreases heading from the plane of the rear face 11b side to the plane of the major surface 11a side.

In the AlₓGa₍₁₋ₓ₎As substrate 10a manufacturing method described above, in the step of growing the AlₓGa₍₁₋ₓ₎As layer 11 (Step S2), preferably an AlₓGa₍₁₋ₓ₎As layer 11 is grown that contains a plurality of laminae in which the amount fraction x of Al monotonically decreases heading from the plane along the layer's interface with the GaAs substrate 13 (from the rear face 11b) to the plane of the layer's major-surface 11a side.

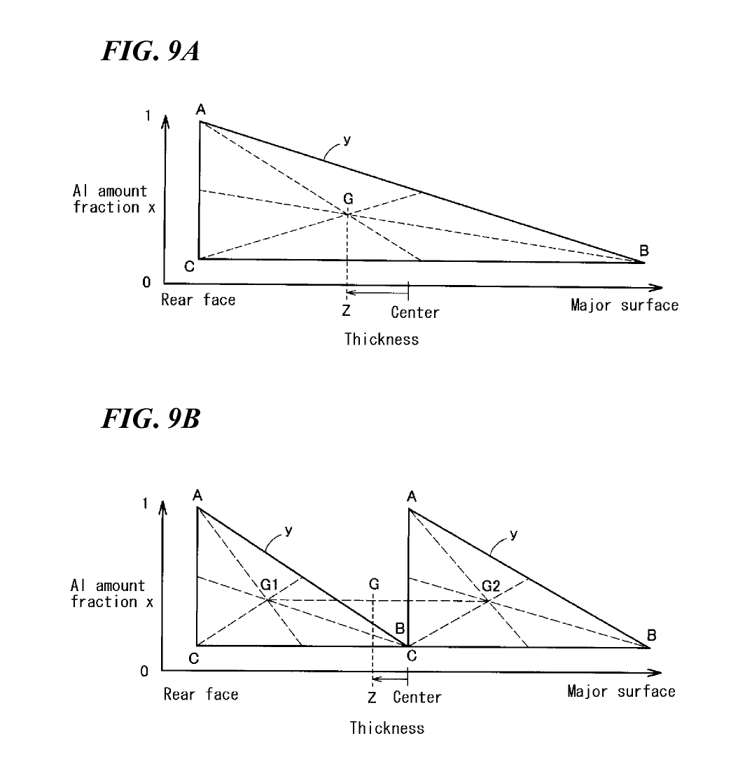

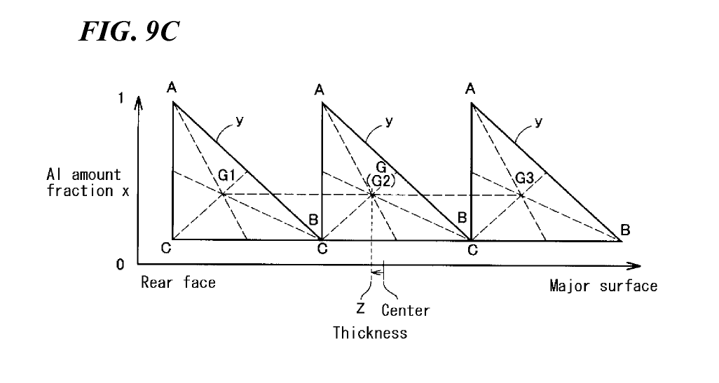

The present inventors discovered that this makes it possible to mitigate warp occurring in the AlₓGa₍₁₋ₓ₎As substrate 10a. Below, with reference to FIGS. 9A through 9C, an explanation will be made of the reasons why. FIG. 9A represents an instance, as indicated in FIG. 2, where the laminar section in which the Al amount fraction x in the AlₓGa₍₁₋ₓ₎As layer 11 monotonically decreases is a single lamina. FIG. 9B represents an instance where in the AlₓGa₍₁₋ₓ₎As layer 11 the laminar section in which the Al amount fraction x monotonically decreases as indicated in FIG. 3 is two laminae. FIG. 9C represents an instance where the laminar section in which the Al amount fraction x monotonically decreases in the AlₓGa₍₁₋ₓ₎As layer 11 is three laminae.

In FIGS. 9A-9C the horizontal axis indicates position thickness-wise traversing from the rear face 11b to the major surface 11a of the AlₓGa₍₁₋ₓ₎As layer 11, while the vertical axis represents the Al amount fraction x in each position in the AlₓGa₍₁₋ₓ₎As layer 11. With the AlₓGa₍₁₋ₓ₎As layers 11 represented in FIGS. 9A-9C, the amount fraction x of Al in the rear faces 11b and in the major surfaces 11a are the same.

In FIGS. 9A-9C, imaginary triangles are formed by a point of intersection (Point C) where, when the highest position (Point A) along the diagonal y representing the amount fraction x of Al is extended downward, and the lowest position (Point B) along the diagonal y is extended leftward, they intersect. The total surface area of these triangles is the stress that is applied to the AlₓGa₍₁₋ₓ₎As layer 11. Warp occurs in the AlₓGa₍₁₋ₓ₎As layer 11 on account of this stress.

The present inventors discovered that warp in the AlₓGa₍₁₋ₓ₎As layer 11 is more likely to appear the greater is the separation z between the geometric center G of the triangles, and the center along the thickness of the AlₓGa₍₁₋ₓ₎As layer 11. The geometric center G is, in the instance illustrated in FIG. 9A, the geometric center G of the triangle formed based on the diagonal y, while in the instances illustrated in FIGS. 9B and 9C, it is the center along a line joining the geometric centers G1 through G3 of triangles formed based on the diagonals y. The geometric center G is where the combined force of the stresses inside the AlₓGa₍₁₋ₓ₎As layer 11 added together acts.

As indicated in FIGS. 9A-9C, the more the number of laminae in which the amount fraction x of Al monotonically decreases, the shorter becomes the separation z from the center along the thickness to the thickness point where the geometric center G is located, and thus the less warp occurs in the AlₓGa₍₁₋ₓ₎As layer 11. Therefore, forming a plurality of laminae in which the amount fraction x of Al monotonically decreases mitigates warp in a AlₓGa₍₁₋ₓ₎As substrate 10a. Herein, with the several triangles in the figures, the maximum and minimum values of the amount fraction x of Al, and the thickness of the AlₓGa₍₁₋ₓ₎As layer 11 are the same, but they do not necessarily have to be made the same: They are adjustable depending on such factors as the transmissivity, warp, and state of the interfaces.

In the above-described AlₓGa₍₁₋ₓ₎As substrate 10a and method of its manufacture, letting ΔAl be the difference in amount fraction Al in two different points thickness-wise through the AlₓGa₍₁₋ₓ₎As layer 11, and letting Δt be the difference in thickness (μm) between the two points, then preferably ΔAl/Δt is greater than 0/μm.

Oxidation toward the major surface 11a is thereby kept under control, making it possible to improve the output power when the AlₓGa₍₁₋ₓ₎As substrate 10a is utilized to fabricate infrared LEDs.

In the above-described AlₓGa₍₁₋ₓ₎As substrate 10a and method of its manufacture, preferably ΔAl/Δt is not greater than 6×10⁻²/μm. That makes it possible to improve the output power when infrared LEDs are fabricated.

### Embodying Mode 2

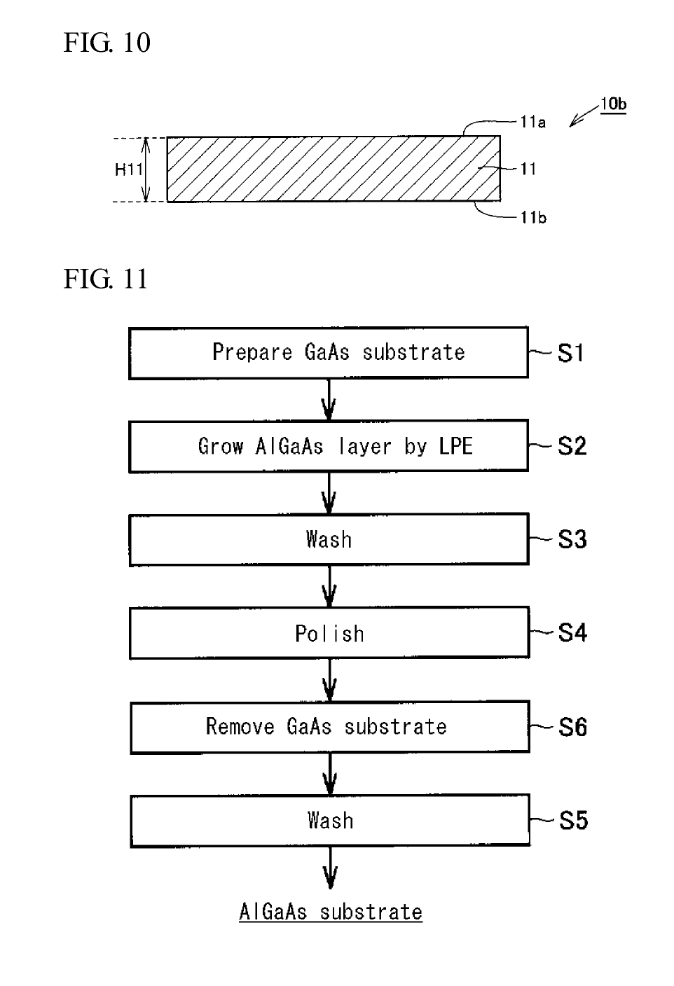

FIG. 10 is a sectional diagram illustratively outlining an AlₓGa₍₁₋ₓ₎As substrate in the present embodying mode. Referring to FIG. 10, an explanation of an AlₓGa₍₁₋ₓ₎As substrate 10b in the present embodying mode will be made.

As represented in FIG. 10, an AlₓGa₍₁₋ₓ₎As substrate 10b in the present embodying mode is furnished with a structural makeup that basically is the same as that of an AlₓGa₍₁₋ₓ₎As substrate 10a of Embodying Mode 1, but differs in that it is not furnished with a GaAs substrate 13.

Specifically, the AlₓGa₍₁₋ₓ₎As substrate 10b is furnished with an AlₓGa₍₁₋ₓ₎As layer 11 having a major surface 11a and, on the reverse side from the major surface 11a, a rear face 11b. Then in the AlₓGa₍₁₋ₓ₎As layer 11, the amount fraction x of Al in the rear face 11b is greater than the amount fraction x of Al in the major surface 11a.

It is preferable that the thickness of an AlₓGa₍₁₋ₓ₎As layer in the present embodying mode be thick enough for the AlₓGa₍₁₋ₓ₎As substrate 10b to be a freestanding substrate. Such height H11 is, for example, 70 μm or more.

To continue: With reference to FIG. 11, an explanation of a method of manufacturing an AlₓGa₍₁₋ₓ₎As substrate 10b in the present embodying mode will be made.

As indicated in FIG. 11, initially, in the same manner as in Embodying Mode 1, Step S1 of preparing a GaAs substrate 13, Step S2 of growing an AlₓGa₍₁₋ₓ₎As layer 11 by LPE, washing Step S3, and polishing Step S4 are implemented. An AlₓGa₍₁₋ₓ₎As substrate 10a as represented in FIG. 1 is thereby manufactured.

Next, the GaAs substrate 13 is removed (Step S6). For the removal method, a technique such as polishing or etching, for example, can be employed. “Polishing” refers to employing a polishing agent such as alumina, colloidal silica, or diamond in grinding equipment such as is fitted with diamond grinding wheels, to mechanically abrade away the GaAs substrate 13. “Etching” refers to carrying out GaAs substrate 13 removal employing an etchant selected by optimally compounding, for example, ammonia, hydrogen peroxide, etc. to have a slow etching rate on AlₓGa₍₁₋ₓ₎As, but a fast etching rate on GaAs.

In instances where the amount fraction x of Al in the rear face 11b of the AlₓGa₍₁₋ₓ₎As layer 11 is 0.12 or more, the selectivity between the GaAs and the AlₓGa₍₁₋ₓ₎As is heightened. The GaAs substrate may therefore be removed with enhanced productivity.

Next, washing Step S5 is implemented in the same manner as in Embodying Mode 1. Implementing the foregoing Steps S1, S2, S3, S4, S6, and S5 makes it possible to manufacture an AlₓGa₍₁₋ₓ₎As substrate 10b as represented in FIG. 10.

It should be understood that apart from that, the AlₓGa₍₁₋ₓ₎As substrate 10b and its method of manufacture are otherwise of the same constitution as the AlₓGa₍₁₋ₓ₎As substrate 10a, and its method of manufacture, in Embodying Mode 1; thus identical components are labeled with identical reference marks, and their explanation will not be repeated.

As described in the foregoing, the AlₓGa₍₁₋ₓ₎As substrate 10b in the present embodying mode is an AlₓGa₍₁₋ₓ₎As substrate 10b furnished with an AlₓGa₍₁₋ₓ₎As layer 11 having a major surface 11a and, on the reverse side from the major surface 11a, a rear face 11b, and is characterized in that in the AlₓGa₍₁₋ₓ₎As layer 11, the amount fraction x of Al in the rear face 11b is greater than the amount fraction x of Al in the major surface 11a.

In addition, a method of manufacturing an AlₓGa₍₁₋ₓ₎As substrate 10b in the present embodying mode is provided with a step (Step S6) of removing the GaAs substrate 13.

According to an AlₓGa₍₁₋ₓ₎As substrate 10b and a method of manufacturing an AlₓGa₍₁₋ₓ₎As substrate 10b in the present embodying mode, an AlₓGa₍₁₋ₓ₎As substrate 10b not furnished with a GaAs substrate 13, but furnished solely with an AlₓGa₍₁₋ₓ₎As layer 11 may be realized. Since the GaAs substrate 13 absorbs light of 900 nm or less wavelength, growing epitaxial layers onto an AlₓGa₍₁₋ₓ₎As substrate 10b from which the GaAs substrate 13 has been removed enables the manufacture of epitaxial wafers for infrared LEDs. Employing such infrared-LED epitaxial wafers to manufacture infrared LEDs enables the realization of infrared LEDs in which a high level of transparency is maintained, and which have superior device characteristics.

In the above-described AlₓGa₍₁₋ₓ₎As substrate 10b and method of its manufacture, preferably the amount fraction x of Al in the rear face 11b of the AlₓGa₍₁₋ₓ₎As layer 11 is not less than 0.12. Implementations in which the amount fraction x of Al is 0.12 or more make it possible to utilize solutions (wet etching techniques), plasmas, different gases (dry etching techniques) and other agents with which etching on GaAs is rapid. The GaAs substrate 13 can therefore be removed by etching whereby the level of selectivity between GaAs and AlₓGa₍₁₋ₓ₎As is high. Consequently, productivity can be enhanced and selective-removal yield rate can be improved. It will be appreciated that in implementations where the AlₓGa₍₁₋ₓ₎As layer 11 includes a plurality of laminae, as long as the amount fraction x of Al in the rear face 11b of the lamina contacting the GaAs substrate 13 (lowermost lamina) is 0.12 or more, the layer will have the same efficacy.

### Embodying Mode 3

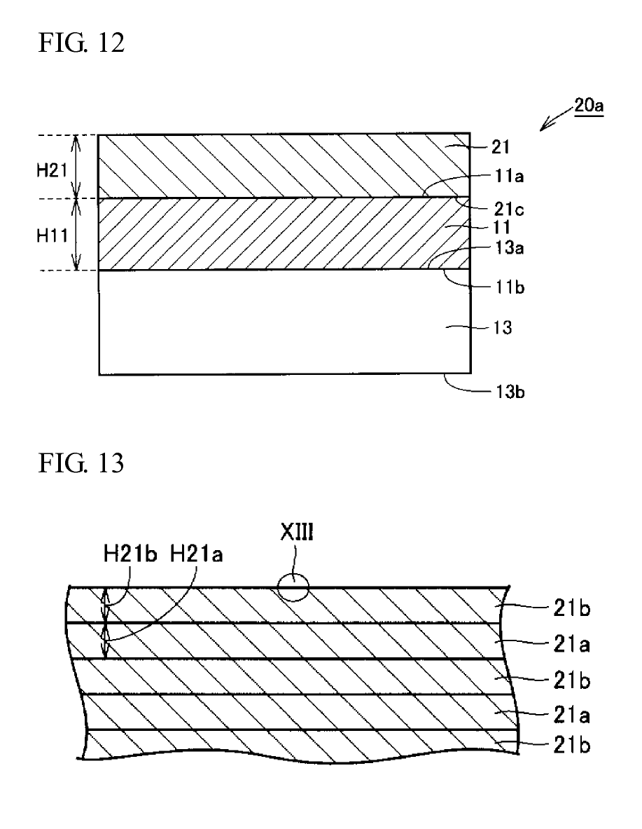

Referring to FIG. 12, an explanation of an epitaxial wafer 20a in the present embodying mode will be made.

As indicated in FIG. 12, the epitaxial wafer 20a is furnished with an AlₓGa₍₁₋ₓ₎As substrate 10a, represented in FIG. 1, of Embodying Mode 1, and, formed onto the major surface 11a of the AlₓGa₍₁₋ₓ₎As layer 11, an epitaxial layer containing an active layer 21. That is, the epitaxial wafer 20a is furnished with a GaAs substrate 13, an AlₓGa₍₁₋ₓ₎As layer 11 formed onto the GaAs substrate 13, and, formed onto the AlₓGa₍₁₋ₓ₎As layer 11, the epitaxial layer containing the active layer 21. The energy bandgap of the active layer 21 is smaller than that of the AlₓGa₍₁₋ₓ₎As layer 11.

It is preferable that the amount fraction x of Al in the active layer 21 in its plane of contact with the AlₓGa₍₁₋ₓ₎As layer 11 (in the active layer's rear face 21c) be larger than the amount fraction x of Al in the AlₓGa₍₁₋ₓ₎As layer 11 in its plane of contact with the active layer 21 (in the present embodying mode, in the layer's major surface 11a). It is also preferable that the amount fraction x of Al in the lamina of greatest thickness in the epitaxial layer containing the active layer 21 be larger than the amount fraction x of Al in the AlₓGa₍₁₋ₓ₎As layer 11 in its plane of contact with the active layer 21 (in the present embodying mode, in the layer's major surface 11a). Such an implementation makes it possible to mitigate warp that occurs in the epitaxial wafer 20a.

It is preferable that the peak concentration of oxygen at the interface between the AlₓGa₍₁₋ₓ₎As layer 11 and the epitaxial layer (in the present embodying mode, the active layer 21) be not greater than 5×10²⁰ atoms/cm³; that it be not greater than 4×10¹⁹ atoms/cm³ is more preferable.

It is preferable that the planar density of oxygen at the interface between the AlₓGa₍₁₋ₓ₎As layer 11 and the epitaxial layer (in the present embodying mode, the active layer 21) be not greater than 2.5×10¹⁵ atoms/cm²; that it be not greater than 3.5×10¹⁴ atoms/cm² is more preferable.

The above-discussed oxygen concentration at the interface between the AlₓGa₍₁₋ₓ₎As layer 11 and the epitaxial layer can be measured by, for example, SIMS.

It is preferable that, as indicated in FIG. 13, the active layer 21 have a multiquantum-well structure.

The active layer 21 contains two or more well layers 21a. The well layers 21a are each sandwiched between barrier layers 21b that are laminae of larger energy bandgap than that of the well layers 21a.

That is, the plurality of well layers 21a and the plurality of barrier layers 21b whose bandgap is larger than that of the well layers 21a are arranged in alternation. With the active layer 21, all of the plurality of well layers 21a may be sandwiched between barrier layers 21b, or the well layers 21a may be arranged on at least one side of the active layer 21, and the well layers 21a arranged on the one side of the active layer 21 may be sandwiched by other layers (not illustrated)—such as guide layers or cladding layers—disposed along the one side, and barrier layers 21b. It should be understood that the region XIII indicated in FIG. 13 is not limited to being an upper portion within the active layer 21.

The active layer 21 preferably has between two and one-hundred both inclusive, more preferably between ten and fifty both inclusive, well layers 21a and barrier layers 21b, respectively. An implementation having two or more well layers 21a as well as barrier layers 21b constitutes a multiquantum-well structure. An implementation having ten or more well layers 21a as well as barrier layers 21b improves light output by improving the optical emission efficiency. Implementations with not more than one-hundred layers allow the costs required in order to build the active layer 21 to be reduced. Implementations with not more than fifty layers allow the costs required in order to build the active layer 21 to be further reduced.

The height H21 of the active layer 21 preferably is between 6 nm and 2 μm both inclusive. The emission intensity may be improved if the height H21 is not less than 6 nm. Productivity may be improved if the thickness H21 is not more than 2 μm.

The height H21a of the well layers 21a preferably is between 3 nm and 20 nm both inclusive. The height H21b of the barrier layers 21b preferably is between 5 nm and 1 μm both inclusive.

While the material constituting the well layers 21a is not particularly limited as long as it has a bandgap that is smaller than that of the barrier layers 21b, materials such as GaAs, AlGaAs, InGaAs (indium gallium arsenide) and AlInGaAs (aluminum indium gallium arsenide) can be utilized. These materials are infrared light-emitting substances whose lattice match with AlGaAs is quite suitable.

In instances where epitaxial wafers 20a are utilized in infrared LEDs whose output wavelength is 900 nm or greater, the material for the well layers 21a preferably contains In, by being InGaAs in which the amount fraction of In is not less than 0.05. And in implementations in which the well layers 21a include a material containing In, preferably the active layer 21 will have not more than four laminae each of the well layers 21a and the barrier layers 21b, and more preferably will have not more than three laminae each of the well layers 21a and the barrier layers 21b.

While the material constituting the barrier layers 21b is not particularly limited as long as it has a bandgap that is larger than that of the well layers 21a, materials such as AlGaAs, InGaP AlInGaP and InGaAsP can be utilized. These materials are substances whose lattice match with AlGaAs is quite suitable.

In instances where epitaxial wafers 20a are utilized in infrared LEDs whose output wavelength is 900 nm or greater, preferably 940 nm or greater, the material for barrier layers 21b inside the active layer 21 preferably contains P, by being GaAsP or AlGaAsP in which the amount fraction of P is not less than 0.05. And in implementations in which the barrier layers 21b include a material containing P, preferably the active layer 21 will have not less than three laminae each of the well layers 21a and the barrier layers 21b.

It is preferable that the concentration of atomic elements apart from the atoms within the epitaxial layer containing the active layer 21 (for example, elements such as atoms within the atmosphere in which growth is carried out) be low.

It will be appreciated that the active layer 21, not particularly limited to being a multiquantum-well structure, may be composed of a single layer, or may be a double-heterostructure.

Also, although in the present embodying mode an implementation in which only the active layer 21 is included as an epitaxial layer has been explained, other layers such as cladding layers and undoped layers may further be included.

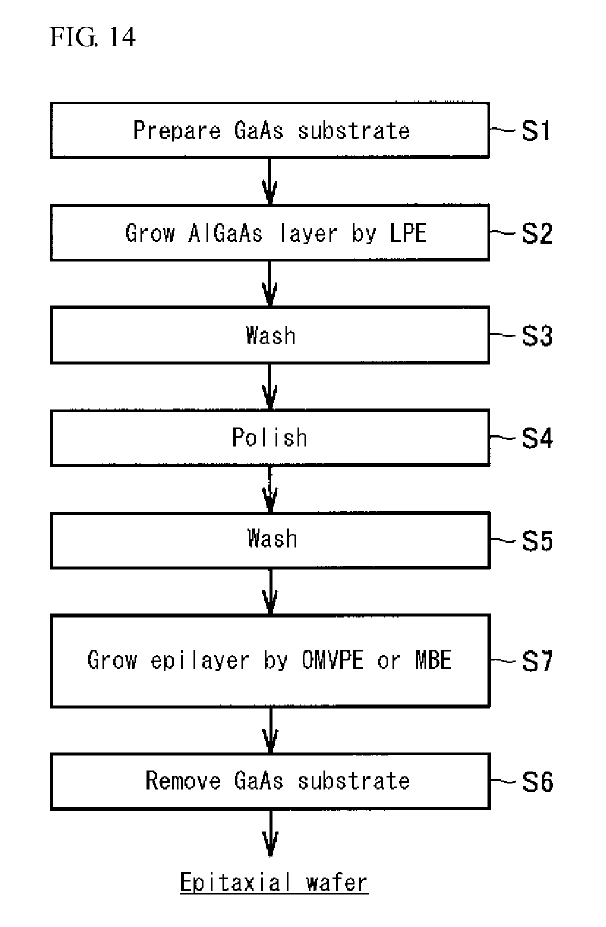

To continue: With reference to FIG. 14, an explanation of a method of manufacturing an infrared-LED epitaxial wafer 20a in the present embodying mode will be made.

As indicated in FIG. 14, initially an AlₓGa₍₁₋ₓ₎As substrate 10a is manufactured by a method in Embodying Mode 1 of manufacturing an AlₓGa₍₁₋ₓ₎As substrate 10a (Steps S1 through S5).

Next, an epitaxial layer containing an active layer 21 is deposited by OMVPE onto the major surface 11a of the AlₓGa₍₁₋ₓ₎As layer 11 (Step S7).

In Step S7, it is preferable that the epitaxial layer (in the present embodying mode, the active layer 21) be formed in such a manner that the amount fraction x of Al in the epitaxial layer in its plane of contact of with the AlₓGa₍₁₋ₓ₎As layer 11 (in the epitaxial layer's rear face 21c) be greater than the amount fraction x of Al in the AlₓGa₍₁₋ₓ₎As layer in its plane of contact with the epitaxial layer (in the major surface 11a in the present embodying mode). It is also preferable that the amount fraction x of Al in the lamina of greatest thickness in the epitaxial layer be greater than the amount fraction x of Al in the AlₓGa₍₁₋ₓ₎As layer 11 in its plane of contact with the epitaxial layer.

Organometallic vapor-phase epitaxy grows an active layer 21 by precursor gases thermal-decomposition reacting above the AlₓGa₍₁₋ₓ₎As layer 11, while molecular-beam epitaxy grows an active layer 21 by a technique that does not mediate the chemical-reaction stages in a non-equilibrium system; thus, the OMVPE and MBE techniques allow the thickness of the active layer 21 to be readily controlled.

An active layer 21 having plural well layers 21a of two or more laminae may therefore be grown.

Furthermore, the height H21 of the epitaxial layer (active layer 21 in the present embodying mode) relative to the height H11 of the AlₓGa₍₁₋ₓ₎As layer 11 (the ratio H21/H11) is, for example, preferably between 0.05 and 0.25 both inclusive, more preferably between 0.15 and 0.25 both inclusive. Such implementations make it possible to mitigate incidence of warp in the state in which an epitaxial layer has been grown onto an AlₓGa₍₁₋ₓ₎As layer 11.

Again, the peak concentration of oxygen at the interface between the AlₓGa₍₁₋ₓ₎As layer 11 and the epitaxial layer (in the present embodying mode, the active layer 21) preferably is not greater than 5×10²⁰ atoms/cm³, more preferably not greater than 4×10¹⁹ atoms/cm³.

Here too the planar density of oxygen at the interface between the AlₓGa₍₁₋ₓ₎As layer 11 and the epitaxial layer (the active layer 21 in the present embodying mode) preferably is not greater than 2.5×10¹⁵ atoms/cm², more preferably not greater than 3.5×10¹⁴ atoms/cm².

In this Step S7, an epitaxial layer containing an active layer 21 as described above is grown onto the AlₓGa₍₁₋ₓ₎As layer 11.

Specifically, an active layer 21 is formed having between two and one-hundred both inclusive, more preferably between ten and fifty both inclusive, well layers 21a and barrier layers 21b, respectively.

It is also preferable that the active layer 21 be grown so as to have a height H21 of from 6 nm to 2 μm. Growing well layers 21a having a height H21a of from 3 nm to 20 nm, and barrier layers 21b having a height H21b of from 5 nm to 1 μm is likewise preferable.

Growing well layers 21a made from GaAs, AlGaAs, InGaAs, AlInGaAs, or the like, and barrier layers 21b made from AlGaAs, InGaP, AlInGaP, GaAsP, AlGaAsP, InGaAsP or the like is also preferable.

For the active layer 21 it does not matter whether there is lattice misalignment (lattice relaxation) in the GaAs and AlGaAs that constitute the AlₓGa₍₁₋ₓ₎As substrate. If there is lattice misalignment in the well layers 21a, lattice misalignment in the opposite direction may be imparted to the barrier layers 21b to balance, for the structure of the epitaxial wafer overall, strain in the crystal from compression—extension. Further, the crystal warpage may be may be at or below, or at or above the lattice-relaxing limit. However, because dislocations threading through the crystal are liable to occur if the warpage is at or above the lattice-relaxing limit, desirably it is at or below the limit.

As an example, an instance in which InGaAs is utilized for the well layers 21a will be given. Because the lattice constant of InGaAs is large with respect to the GaAs substrate, lattice relaxation occurs if an epitaxial layer of a fixed thickness or greater is grown. Therefore, favorable crystal in which the occurrence of crystal-threading dislocations is kept to a minimum can be obtained by having the thickness be below the level at which lattice relaxation occurs.

Likewise, if GaAsP is utilized for the barrier layers 21b, because the lattice constant of GaAsP is small relative to the GaAs substrate, lattice relaxation occurs when epitaxial layer of fixed thickness or greater is grown thereon. Therefore, favorable crystal in which the occurrence of crystal-threading dislocations is kept to a minimum can be obtained by having the thickness be below the level at which lattice relaxation occurs.

Lastly, taking advantage of the features that with respect to the GaAs substrate the lattice constant of InGaAs is large while the lattice constant of GaAsP is small, by utilizing InGaAs for the well layers 21a and GaAsP for the barrier layers 21b to balance out the lattice warp in the crystal as a whole, favorable crystal in which the occurrence of crystal-threading dislocations is kept to a minimum can be obtained up to or above the thickness levels just mentioned, without causing lattice relaxation.

By implementing the foregoing Steps S1 through S5 and S7, the epitaxial wafer 20a depicted in FIG. 12 may be manufactured.

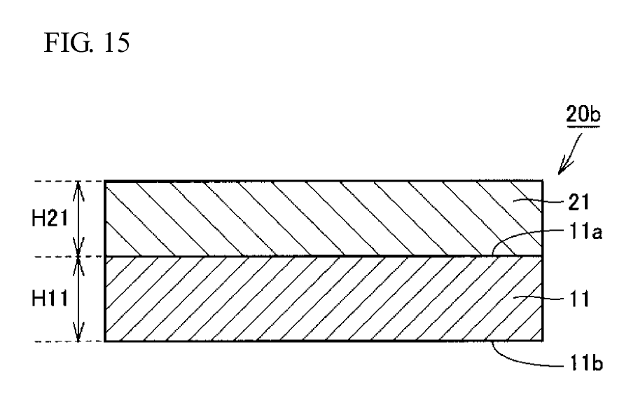

It will be appreciated that Step S6 of removing the GaAs substrate 13 may be additionally be implemented. Step S6 here may be implemented, for example, after Step S7 of growing an epitaxial layer, but is not particularly limited to that sequence. Step S6 may be implemented in between polishing Step S4 and washing Step S5, for example. Step S6 here is the same as Step S6 of Embodying Mode 2 and thus its explanation will not be repeated. In instances in which Step S6 is carried out, a structure that is the same as that of later-described epitaxial wafer 20b of FIG. 15 results.

As described in the foregoing, an infrared-LED epitaxial wafer 20a in the present embodying mode is furnished with an AlₓGa₍₁₋ₓ₎As substrate 10a of Embodying Mode 1, and an epitaxial layer, formed on the major surface 11a of the AlₓGa₍₁₋ₓ₎As layer 11 in the AlₓGa₍₁₋ₓ₎As substrate 10a, and containing an active layer 21.

Furthermore, a method of manufacturing an infrared-LED epitaxial wafer 20a in the present embodying mode is provided with a process (Steps S1 through S6) of manufacturing an AlₓGa₍₁₋ₓ₎As substrate 10a by an AlₓGa₍₁₋ₓ₎As substrate 10a manufacturing method of Embodying Mode 1, and a step (Step S7) of forming an epitaxial layer containing an active layer 21 onto the major surface 11a of the AlₓGa₍₁₋ₓ₎As layer 11 by at least either OMVPE or MBE.

According to an infrared-LED epitaxial wafer 20a, and a method of its manufacture, in the present embodying mode, an epitaxial layer is formed onto an AlₓGa₍₁₋ₓ₎As substrate 10a furnished with an AlₓGa₍₁₋ₓ₎As layer 11 in which the amount fraction x of Al in its major surface 11a is lower than in its rear face 11b. Consequently, an infrared-LED epitaxial wafer 20a can be realized in which a high level of transparency is maintained, and with which, when the epitaxial wafer 20a is utilized to fabricate a semiconductor device, the device proves to have superior characteristics.

In the above-described infrared-LED epitaxial wafer 20a and method of is manufacture, it is preferable that the amount fraction x of Al in the epitaxial layer in its plane of contact with the AlₓGa₍₁₋ₓ₎As layer 11 (in the reverse face 21c of the epitaxial layer) be greater than the amount fraction x of Al in the AlₓGa₍₁₋ₓ₎As layer 11 in its plane of contact with the epitaxial layer (in the major surface 11a).

These conditions, when the AlₓGa₍₁₋ₓ₎As layer 11 and the epitaxial layer are regarded as a whole, can mitigate warp in the epitaxial wafer 20a, for the same reasons discussed in Embodying Mode 1.

In the above-described method of manufacturing an infrared-LED epitaxial wafer 20a, preferably provided are: a step of preparing a GaAs substrate 13 (Step S1); a step of growing onto the GaAs substrate 13 by LPE an AlₓGa₍₁₋ₓ₎As layer 11 as a window layer that diffuses current and that will transmit light from the active layer (Step S2); a step of polishing the major surface 11a of the AlₓGa₍₁₋ₓ₎As layer 11 (Step S4); and a step growing onto the major surface 11a of the AlₓGa₍₁₋ₓ₎As layer 11, by at least either OMVPE or MBE, an active layer 21 having a multiquantum-well structure and whose energy bandgap is smaller than that of the AlₓGa₍₁₋ₓ₎As layer 11 (Step S7).

Owing to the AlₓGa₍₁₋ₓ₎As layer 11 being grown (Step S2) by the LPE technique, the growth rate is rapid. With LPE, moreover, since expensive precursor gases and expensive apparatus need not be employed, the manufacturing costs are low. Therefore, more than with the OMVPE and MBE techniques, costs can be reduced and considerably thick AlₓGa₍₁₋ₓ₎As layers 11 formed. Unevenness on the major surface 11a of the AlₓGa₍₁₋ₓ₎As layer 11 can be reduced by polishing the major surface 11a of the AlₓGa₍₁₋ₓ₎As layer 11. Therefore, in forming onto the major surface 11a of the AlₓGa₍₁₋ₓ₎As layer 11 an epitaxial layer containing an active layer 21, abnormal growth of the epitaxial layer containing the active layer 21 can be kept under control. Meanwhile, OMVPE, by the thermal-decomposition reaction of the precursor gases, and MBE, which does not mediate the chemical-reaction stages in a non-equilibrium system, allow the film thickness to be optimally controlled. Consequently, forming the epitaxial layer containing the active layer 21 by OMVPE or MBE after Step S4 of polishing the major surface 11a enables abnormal growth to be held in check, and makes it possible to form an active layer having a multiquantum-well structure (MQW structure) in which the film thickness of the active layer 21 has been optimally controlled.

Especially since with LEDs, cases where the film thickness is less than with laser diodes (LDs) are numerous, utilizing the OMVPE or MBE techniques, whereby film-thickness controllability is excellent, allows an epitaxial layer containing an active layer 21 having a multiquantum-well structure to be formed.

Here the active layer 21 is grown by OMVPE or MBE following Step S2 of growing the AlₓGa₍₁₋ₓ₎As layer 11 by LPE. Growing the active layer 21 by OMVPE or MBE after the liquid-phase epitaxy prevents extended-duration, high-temperature heat from being applied to the active layer 21. Deterioration of crystallinity due to crystalline defects arising in the active layer 21 on account of the high-temperature heat can therefore be prevented, and diffusion into the active layer 21 of dopants introduced by the LPE can held in check.

After Step S7 of growing the active layer 21 in the present embodying mode, the active layer 21 is not exposed to the high-temperature ambients employed in liquid-phase epitaxy, and thus p-type dopants for example, which diffuse readily, introduced into the AlₓGa₍₁₋ₓ₎As layer 11 may be prevented from diffusing to inside the active layer 21. This allows the concentration in the active layer 21 of p-type carriers such as Zn, Mg and C to be held low—to, for example, 1×10¹⁸ cm⁻³ or under. Problems owing to such carriers, such as the formation of impurity bands in the active layer 21, therefore may be prevented, allowing the difference in bandgap between the well layers 21a and the barrier layers 21b to be sustained.

Accordingly, since an active layer 21 having an improved-performance multiquantum-well structure may be formed, when the GaAs substrate 13 is removed (Step S6) and the device electrodes formed, by the altering of the state density in the active layer 21 efficient recombination of electrons and holes takes place. Epitaxial wafers 20a for constituting improved-emission-efficiency infrared LEDs can therefore be grown.

It will be appreciated that with the AlₓGa₍₁₋ₓ₎As layer 11 as a window layer, since electric current is diffused in a direction (horizontally in FIG. 1) that intersects the direction along which the AlₓGa₍₁₋ₓ₎As layer 11 and the active layer 21 are laminated (vertically in FIG. 1), the light-extraction efficiency is improved, thereby allowing the optical emission efficiency to be improved.

In the above-described method of manufacturing an infrared-LED epitaxial wafer 20a, it is preferable that Steps S3 and S5 of washing the surface of the AlₓGa₍₁₋ₓ₎As layer 11 be provided at least either between AlₓGa₍₁₋ₓ₎As layer 11 growth Step S2 and polishing Step S4, or between polishing Step S4 and epitaxial layer growth Step S7.

Even should impurities cling to or mix into the AlₓGa₍₁₋ₓ₎As layer 11 due to the AlₓGa₍₁₋ₓ₎As layer 11 coming into contact with atmospheric air, thus providing the washing steps lets the impurities be cleared away.

In the above-described method of manufacturing an infrared-LED epitaxial wafer 20a, it is preferable that in washing Steps S3 and S5, an alkaline solution be employed to wash the major surface 11a.

When impurities have clung to or mixed into the AlₓGa₍₁₋ₓ₎As layer 11, this preferred application of the washing steps allows the impurities to be more effectively removed from the AlₓGa₍₁₋ₓ₎As layer 11.

In the above-described infrared-LED epitaxial wafer 20a and method of its manufacture, it is preferable that the height H11 of the AlₓGa₍₁₋ₓ₎As layer 11 be between 10 μm and 1000 μm both inclusive, and more preferable that it be between 20 μm and 140 μm both inclusive.

Implementations in which the height H11 is as least 10 μm allow optical emission efficiency to be improved. Implementations in which the height H11 is 20 μm or more enable further improvement of optical emission efficiency. Keeping the height H11 to 1000 μm or less reduces the costs required to form the AlₓGa₍₁₋ₓ₎As layer 11. Keeping the height H11 to 140 μm or less further allows the costs involved in the deposition of the AlₓGa₍₁₋ₓ₎As layer 11 to be held down.

In the above-described infrared-LED epitaxial wafer 20a and method of its manufacture, it is preferable that in the active layer 21, the well layers 21a and the barrier layers 21b, of bandgap larger than that of the well layers 21a, be disposed in alternation, and that the active layer 21 has between ten and fifty well layers 21a (both inclusive) and between ten and fifty barrier layers 21b (both inclusive).

Implementations with ten or more layers allow further improvement in optical emission efficiency, while implementations with no more than fifty layers allow the costs involved in forming the active layer 21 to be held down.

In the foregoing infrared-LED epitaxial wafer 20a and method of its manufacture, preferably the peak concentration of oxygen in the major surface 11a of the AlₓGa₍₁₋ₓ₎As layer 11 is not greater than 5×10²⁰ atoms/cm³. Likewise, in the above-described infrared-LED epitaxial wafer 20a and method of its manufacture, preferably the planar density of oxygen in the major surface 11a of the AlₓGa₍₁₋ₓ₎As layer is not greater than 2.5×10¹⁵ atoms/cm².

This allows reduction in the oxygen peak concentration at the interface and the planar oxygen density when an epitaxial layer is deposited onto the major surface 11a. The output power when the AlₓGa₍₁₋ₓ₎As substrate 10a is utilized to fabricate infrared LEDs can therefore be improved.

With the foregoing infrared-LED epitaxial wafer 20a and method of its manufacture, preferably they are an epitaxial wafer utilized in infrared LEDs whose emission wavelength is 900 nm or greater, and a method of manufacturing such a wafer, wherein the well layers 21a inside the active layer 21 include a material containing In, and the well layers 21a number four or fewer laminae. The emission wavelength mmor preferably is 940 nm or greater.

By forming an active layer 21 including a material containing In and having four or fewer well layers, the present inventors discovered that lattice relaxation was kept under control. They therefore were able to realize an epitaxial wafer that can be utilized in infrared LEDs whose wavelength is 900 nm or greater.

In the foregoing infrared-LED epitaxial wafer 20a and method of its manufacture, preferably the well layers 21a are of InGaAs in which the amount fraction of indium is 0.05 or greater.

That makes it possible to realize a useful epitaxial wafer 20a that can be utilized in infrared LEDs whose wavelength is 900 nm or greater.

With the above-described epitaxial wafer 20a for infrared LEDs and the method of its manufacture, preferably they are an epitaxial wafer utilized in an infrared LED whose emission wavelength is 900 nm or greater, and a method of manufacturing such a wafer, wherein the barrier layers 21b inside the active layer 21 include a material containing P, with the number of barrier layers 21b being three or more laminae.

By forming an active layer 21 including a material containing P, the present inventors discovered that lattice relaxation was kept to a minimum. They therefore were able to realize an epitaxial wafer that can be utilized in infrared LEDs whose wavelength is 900 nm or greater.

In the foregoing infrared-LED epitaxial wafer and method of its manufacture, preferably the barrier layers 21b are of either GaAsP or AlGaAsP in which the amount fraction of P is 0.05 or greater.

That makes it possible to realize a useful epitaxial wafer 20a that can be utilized in infrared LEDs whose wavelength is 900 nm or greater.

### Embodying Mode 4

Referring to FIG. 15, an explanation of an infrared-LED epitaxial wafer 20b in the present embodying mode will be made.

As indicated in FIG. 15, an epitaxial wafer 20b in the present embodying mode is furnished with an AlₓGa₍₁₋ₓ₎As substrate 10b set out in Embodying Mode 2, represented in FIG. 10, and, formed onto the major surface 11a of the AlₓGa₍₁₋ₓ₎As layer 11, an epitaxial layer containing an active layer 21.

An epitaxial wafer 20b in the present embodying mode is furnished with a structural makeup that basically is the same as that of an epitaxial wafer 20a of Embodying Mode 3, but differs in that it is not furnished with a GaAs substrate 13.

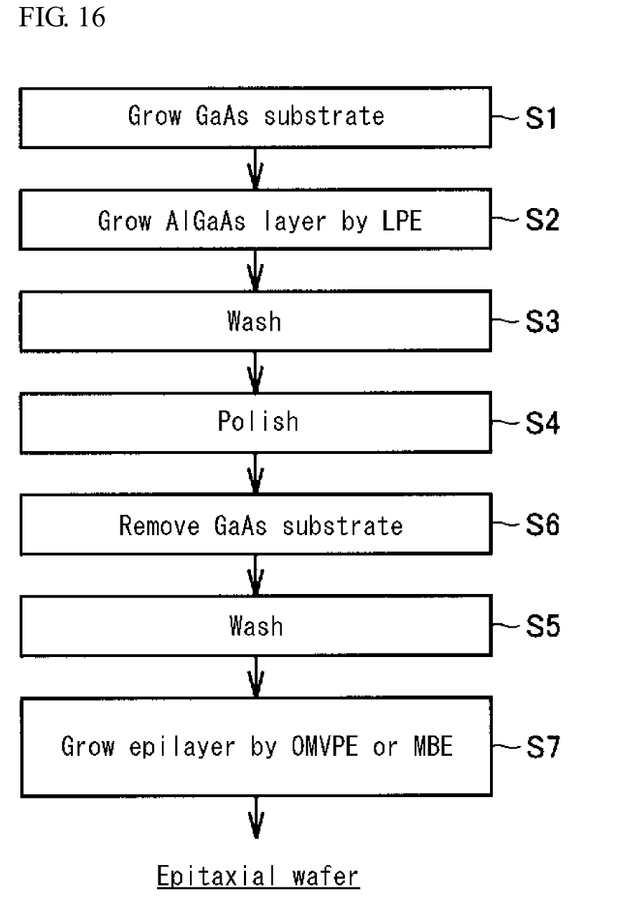

To continue: With reference to FIG. 16, an explanation of a method of manufacturing an epitaxial wafer 20b in the present embodying mode will be made.

As indicated in FIG. 16, initially an AlₓGa₍₁₋ₓ₎As substrate 10b is manufactured by a method in Embodying Mode 2 of manufacturing an AlₓGa₍₁₋ₓ₎As substrate 10b (Steps S1, S2, S3, S4, S6 and S5).

Next, in the same manner as in Embodying Mode 3, an epitaxial layer containing an active layer 21 is deposited by OMVP onto the major surface 11a of the AlₓGa₍₁₋ₓ₎As layer 11 (Step S7).

Implementing the foregoing Steps S1 through S7 enables an infrared-LED epitaxial wafer 20b, represented in FIG. 15, to be manufactured.

It should be understood that apart from the foregoing, the infrared-LED epitaxial wafer and its method of manufacture are otherwise of the same constitution as the infrared-LED epitaxial wafer 20a and its method of manufacture in Embodying Mode 3; thus identical components are labeled with identical reference marks, and their explanation will not be repeated.

As described in the foregoing, the infrared-LED epitaxial wafer 20b in the present embodying mode is furnished with an AlₓGa₍₁₋ₓ₎As layer 11, and an epitaxial layer formed on the major surface 11a of the AlₓGa₍₁₋ₓ₎As layer 11 and containing an active layer 21.

In addition, a method of manufacturing an infrared-LED epitaxial wafer 20b in the present embodying mode is provided with a step (Step S6) of removing the GaAs substrate 13.

According to an infrared-LED epitaxial wafer 20b and its method of manufacture in the present embodying mode, an AlₓGa₍₁₋ₓ₎As substrate 10b from which the GaAs substrate, which absorbs light in the visible range, has been removed is utilized. Consequently, further forming electrodes on the epitaxial wafer 20b enables the realization of an infrared-LED-constituting epitaxial wafer 20b in which a high level of transparency is sustained and superior device characteristics are maintained.

### Modified Example

Referring to FIG. 27, an explanation of an infrared-LED epitaxial wafer 20d of the present modified example of an embodying mode will be made. As represented in FIG. 27, the epitaxial wafer 20d in the modified example is furnished with basically the same structural makeup as the epitaxial wafer 20b represented in FIG. 15, but differs in that the epitaxial layer further includes a buffer layer 25.

The buffer layer 25 has a plane of contact with the AlₓGa₍₁₋ₓ₎As layer 11. In sum, the epitaxial wafer 20d in the modified example is furnished with an AlₓGa₍₁₋ₓ₎As layer 11, a buffer layer 25 formed onto the AlₓGa₍₁₋ₓ₎As layer 11, and an active layer 21 formed onto the buffer layer 25.

The buffer layer 25 contains Al, with the amount fraction x of Al in the buffer layer 25 being lower than the amount fraction x of Al in the active layer 21. The amount fraction x of Al in the active layer 21 herein signifies the average Al amount fraction in the active layer 21 overall, or the Al amount fraction in the cladding layers inside the active layer 21.

If the amount fraction x of Al in the buffer layer 25 is lower than the amount fraction x of Al in the active layer 21, then the Al amount fraction x in the buffer layer 25 may be lower also than the Al amount fraction x in the AlₓGa₍₁₋ₓ₎As layer 11 in its plane of contact with the epitaxial layer (in the present embodying mode, the buffer layer 25). That is, the amount fraction x of Al will be: AlₓGa₍₁₋ₓ₎As layer 11>buffer layer 25<active layer 21. Put differently still, the Al amount fraction will include instances in which active layer 21>AlₓGa₍₁₋ₓ₎As layer 11, and instances in which active layer 21<AlₓGa₍₁₋ₓ₎As layer 11.

Further, if the amount fraction x of Al in the buffer layer 25 is lower than the amount fraction x of Al in the active layer 21, and if the amount fraction x of Al in the epitaxial layer in its plane of contact with the AlₓGa₍₁₋ₓ₎As layer 11 is higher than the amount fraction x of Al in the AlₓGa₍₁₋ₓ₎As layer 11 in its plane of contact with the epitaxial layer, than the amount fraction x of Al will be: AlₓGa₍₁₋ₓ₎As layer 11<buffer layer 25<active layer 21.

A method of manufacturing an epitaxial wafer in the modified example is provided with basically the same constitution as that of Embodying Mode 4, but in Step S7 of forming the epitaxial layer, an epitaxial layer further including a buffer layer 25 having a plane of contact with the AlₓGa₍₁₋ₓ₎As layer 11 is formed.

Specifically, after the AlₓGa₍₁₋ₓ₎As layer 11 is manufactured, the buffer layer 25 is formed onto the major surface 11a of the AlₓGa₍₁₋ₓ₎As layer 11. The method of forming the buffer layer 25 is not particularly limited; the layer can be formed by techniques such as OMVPE and MBE. Thereafter, the active layer 21 is formed onto the buffer layer. The buffer layer 25 preferably contains Al, with the amount fraction x of Al being as stated above.

As described in the foregoing, in a modified example of Embodying Mode 4, with an epitaxial wafer 20d for infrared LEDs, the amount fraction x of Al in the epitaxial layer in its plane of contact with the AlₓGa₍₁₋ₓ₎As layer 11 is higher than the amount fraction x of Al in the AlₓGa₍₁₋ₓ₎As layer 11 in its plane of contact with the epitaxial layer, and the epitaxial layer further includes a buffer layer 25 having a plane of contact with the AlₓGa₍₁₋ₓ₎As layer 11, with the amount fraction x of Al in the buffer layer being lower than the amount fraction x of Al in the active layer 21.

With the above-described method of manufacturing an infrared-LED epitaxial wafer 20d, the amount fraction x of Al in the epitaxial layer in its plane of contact with the AlₓGa₍₁₋ₓ₎As layer 11 is higher than the amount fraction x of Al in the AlₓGa₍₁₋ₓ₎As layer 11 in its plane of contact with the epitaxial layer, and in Step S7 of forming the epitaxial layer, an epitaxial layer further including a buffer layer 25 having a plane of contact with the AlₓGa₍₁₋ₓ₎As layer 11 is formed, with the amount fraction x of Al in the buffer layer 25 being lower than the amount fraction x of Al in the active layer 21.

Again, in an infrared-LED epitaxial wafer 20d in the modified example, the epitaxial layer further includes the buffer layer 25 having a plane of contact with the AlₓGa₍₁₋ₓ₎As layer 11, while the Al amount fraction x in the buffer layer 25 may be lower than the Al amount fraction x in the AlₓGa₍₁₋ₓ₎As layer 11 in its plane of contact with the epitaxial layer, and lower than the Al amount fraction x in the active layer 21.

With the just-described method of manufacturing an infrared-LED epitaxial wafer 20d, in Step S7 of forming the epitaxial layer, the epitaxial layer further including the buffer layer 25 having a plane of contact with the AlₓGa₍₁₋ₓ₎As layer 11 is formed, wherein the Al amount fraction x in the buffer layer 25 may be lower than the Al amount fraction x in the AlₓGa₍₁₋ₓ₎As layer 11 in its plane of contact with the epitaxial layer, and lower than the Al amount fraction x in the active layer 21.

The present inventors discovered, as the result of intensive research efforts, that forming an epitaxial layer including a buffer layer 25 in which the amount fraction x of Al has been controlled in the manner described above allows the absolute value of, and irregularities in, the forward voltage (V_{f}) to be effectively reduced.

Following the manufacture of an AlₓGa₍₁₋ₓ₎As substrate including an AlₓGa₍₁₋ₓ₎As layer 11, in some cases the substrate is exposed to atmospheric air until the epitaxial layer is formed. Although the substrate of the present embodying mode is effective to diminish formation of an oxide layer on the major surface 11a of the AlₓGa₍₁₋ₓ₎As layer 11, it can happen that due to reaction with air, an oxide layer forms. If the active layer 21, whose oxidizing reactivity is high, is formed contacting on the major surface 11a of the AlₓGa₍₁₋ₓ₎As layer 11, defects owing to the reaction of Al and oxygen will develop in between the AlₓGa₍₁₋ₓ₎As layer 11 and the active layer. This proves to be a factor causing electrical V_{f} increase and irregularities. Nevertheless, in the modified example, the fact that a buffer layer 25 having an Al amount fraction that is lower than the amount fraction of Al in the active layer 21 is formed onto the major surface 11a of the AlₓGa₍₁₋ₓ₎As layer 11 allows defects to be effectively controlled from forming at the interface between the AlₓGa₍₁₋ₓ₎As layer 11 and the epitaxial layer. The V_{f} characteristics of infrared LEDs furnished with the epitaxial wafer 20d can be improved as a result.

### Embodying Mode 5

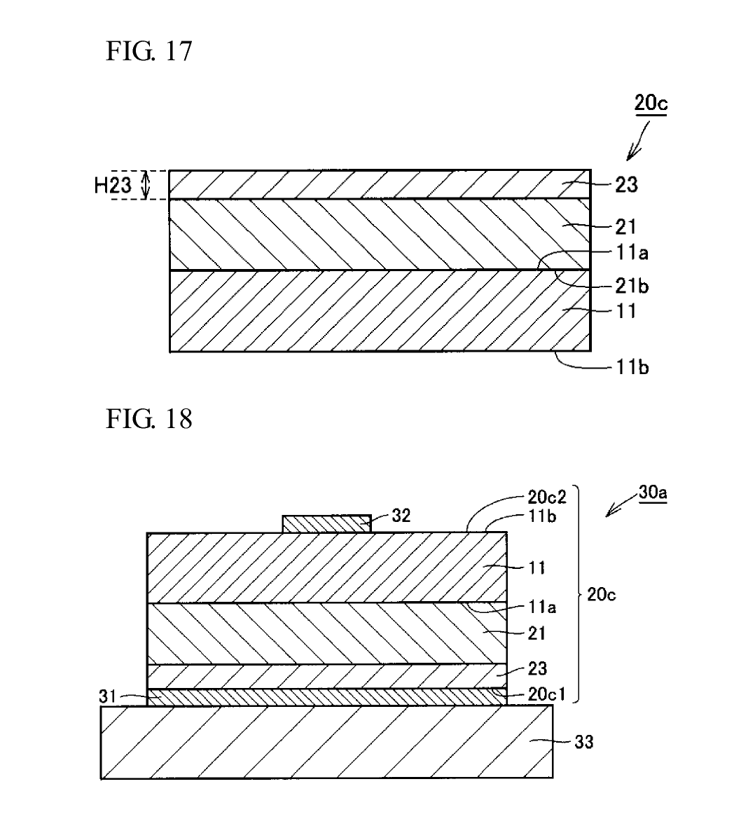

Referring to FIG. 17, an explanation of an infrared-LED epitaxial wafer 20c in the present embodying mode will be made.

As indicated in FIG. 17, an epitaxial wafer 20c in the present embodying mode is furnished with basically the same structural makeup as that of an epitaxial wafer 20b of Embodying Mode 4, but differs in that the epitaxial layer further includes a contact layer 23. That is, in the present embodying mode, the epitaxial layer contains an active layer 21 and a contact layer 23.

Specifically, the epitaxial wafer 20c is furnished with an AlₓGa₍₁₋ₓ₎As layer 11, an active layer 21 formed onto the AlₓGa₍₁₋ₓ₎As layer 11, and a contact layer 23 formed onto the active layer 21.

The contact layer 23 consists of, for example, p-type GaAs and has a height H23 of 0.01 μm or more.

To continue: A method of manufacturing an infrared-LED epitaxial wafer 20c in the present embodying mode will be made. The method of manufacturing an infrared-LED epitaxial wafer 20c in the present embodying mode is furnished with the same constitution as the epitaxial wafer 20b manufacturing method of Embodying Mode 4, but differs in that Step S7 of forming an epitaxial layer further includes a substep of forming a contact layer 23.

Specifically, after the active layer 21 is grown, a contact layer 23 is formed onto the surface of the active layer 21. Although the method whereby the contact layer 23 is formed is not particularly limited, preferably it is grown by at least either OMVPE or MBE, or else by a combination of the two, because these deposition techniques enable the formation of thin-film layers. And the contact layer 23 is preferably grown by the same technique as is the active layer 21, because it can then be grown continuously with growth of the active layer 21.

It should be understood that apart from the foregoing, the infrared-LED epitaxial wafer 20c and its method of manufacture are otherwise of the same constitution as the infrared-LED epitaxial wafer 20b and its method of manufacture in Embodying Mode 4; thus identical components are labeled with identical reference marks, and their explanation will not be repeated.

It will be appreciated that the infrared-LED epitaxial wafer 20c and its method of manufacture in the present embodying mode can find application not only in Embodying Mode 4, but in Embodying Mode 3 as well.

### Embodying Mode 6

Referring to FIG. 18, an explanation of an infrared LED 30a in the present embodying mode will be made. As indicated in FIG. 18, an infrared LED 30a in the present embodying mode is furnished with an infrared-LED epitaxial wafer 20c, represented in FIG. 17, of Embodying Mode 5, electrodes 31 and 32, formed respectively on the front side 20c1 and back side 20c2 of the epitaxial wafer 20c, and a stem 33.

The electrode 31 is provided contacting on the front side 20c1 of the epitaxial wafer 20c (on the contact layer 23 in the present embodying mode), while the electrode 32 is provided contacting on the back side 20c2 (on the AlₓGa₍₁₋ₓ₎As layer 11 in the present embodying mode). The stem 33 is provided contacting on the electrode 31, on its reverse side from the epitaxial wafer 20c.

To give specifics of the LED 30a makeup: The stem 33 is constituted from, for example, an iron-based material. The electrode 31 is a p-type electrode constituted from, for example, an alloy of gold (Au) and zinc (Zn). The electrode 31 is formed onto the p-type contact layer 23. The contact layer 23 is formed on the top of the active layer 21. The active layer 21 is formed on the top of the AlₓGa₍₁₋ₓ₎As layer 11. The electrode 32 formed onto the AlₓGa₍₁₋ₓ₎As layer 11 is an n-type electrode constituted from, for example, an alloy of Au and Ge (germanium).

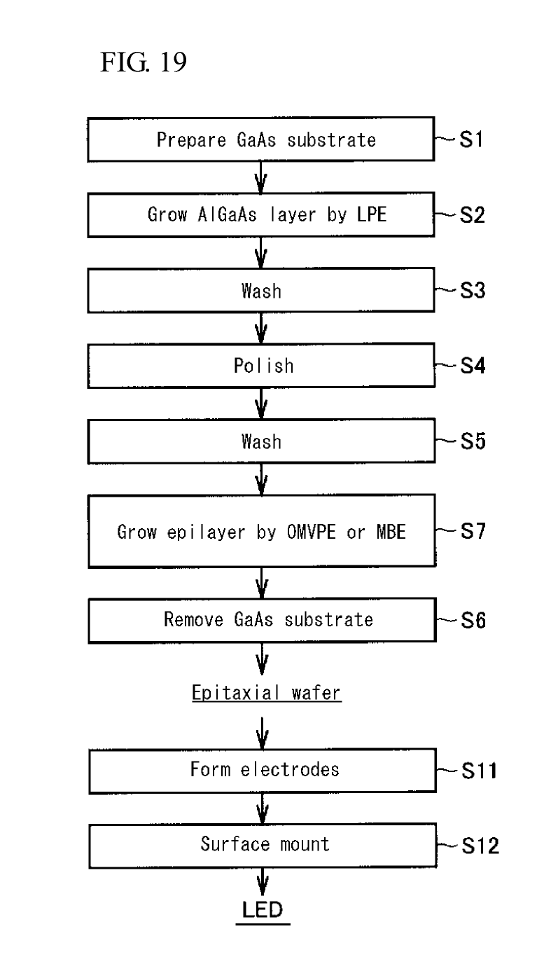

To continue: With reference to FIG. 19, an explanation of a method of manufacturing an infrared LED 30a in the present embodying mode will be made.

Initially, an epitaxial wafer 20a is manufactured by the procedure of Embodying Mode 3 for manufacturing an infrared-LED epitaxial wafer 20a (Steps S1 through S5, and S7). In this case, the active layer 21 and the contact layer 23 are formed in Step S7 of growing an epitaxial layer. Next, the GaAs substrate is removed (Step S6). It will be appreciated that implementing Step S6 allows an infrared-LED epitaxial wafer 20c as represented in FIG. 17 to be manufactured.

Subsequently, electrodes 31 and 32 are formed on the front side 20c1 and back side 20c2 of the infrared-LED epitaxial wafer 20c (Step S11). Specifically, by a vapor-deposition technique, for example, Au and Zn are vapor-deposited onto the front side 20c1, and further, Au and Ge are alloyed after being vapor-deposited onto the back side 20c2, to form the electrodes 31 and 32.

Next, the LED is surface mounted (Step S12). To give a specific example: The electrode 31 side is turned down, and die attachment is carried out on the stem 33 with a die-attach adhesive such as an Ag paste, or with a eutectic alloy such as AuSn.

Implementing the aforedescribed Steps S1 through S12 enables an infrared-LED 30a, represented in FIG. 18, to be manufactured.

It should be understood that in the present embodying mode, although an implementation utilizing an Embodying Mode 5 epitaxial wafer 20c for infrared LEDs has been described, an infrared-LED epitaxial wafer 20a or 20b of Embodying Modes 3 or 4 is also applicable. Prior to completion of the infrared LED, however, Step S6 of removing the GaAs substrate 13 may be implemented.

As described in the foregoing, an infrared LED 30a in the present embodying mode is furnished with: an AlₓGa₍₁₋ₓ₎As substrate 10b of Embodying Mode 2; an epitaxial layer formed onto the major surface 11a of the AlₓGa₍₁₋ₓ₎As layer 11 and including an active layer 21; a first electrode 31, formed on the front side 20c1 of the epitaxial layer; and a second electrode 32, formed on the back side 20c2 of the AlₓGa₍₁₋ₓ₎As layer 11.

In turn, an infrared LED 30a in the present embodying mode is furnished with: a process of manufacturing an AlₓGa₍₁₋ₓ₎As substrate 10b by an AlₓGa₍₁₋ₓ₎As substrate 10b manufacturing method of Embodying Mode 2 (Steps S1 through S6); a step of forming an epitaxial layer containing an active layer 21 onto the major surface 11a of the AlₓGa₍₁₋ₓ₎As layer 11 by OMVPE (Step S7); a step of forming a first electrode 31 onto the front side 20c1 of the epitaxial wafer 20c (Step S11); and a step of forming a second electrode 32 onto the rear face 11b of the AlₓGa₍₁₋ₓ₎As layer 11 (Step S11).

According to an infrared LED 30a and method of its manufacture in the present embodying mode, since an AlₓGa₍₁₋ₓ₎As substrate 10b in which the amount fraction x of Al in the AlₓGa₍₁₋ₓ₎As layer 11 has been controlled is utilized, infrared LEDs 30a that sustain a high level of transmissivity and which, in the fabrication of semiconductor devices, have superior characteristics may be realized.

Furthermore, the electrode 31 is formed on the wafer's active layer 21 side, while the electrode 32 is formed on its AlₓGa₍₁₋ₓ₎As layer 11 side. This structure enables current from the electrode 32 to be more diffused across the entire surface of the infrared LED 30a by means of the AlₓGa₍₁₋ₓ₎As layer 11. Infrared LEDs 30a of further improved optical emission efficiency can therefore be obtained.

### Modified Example

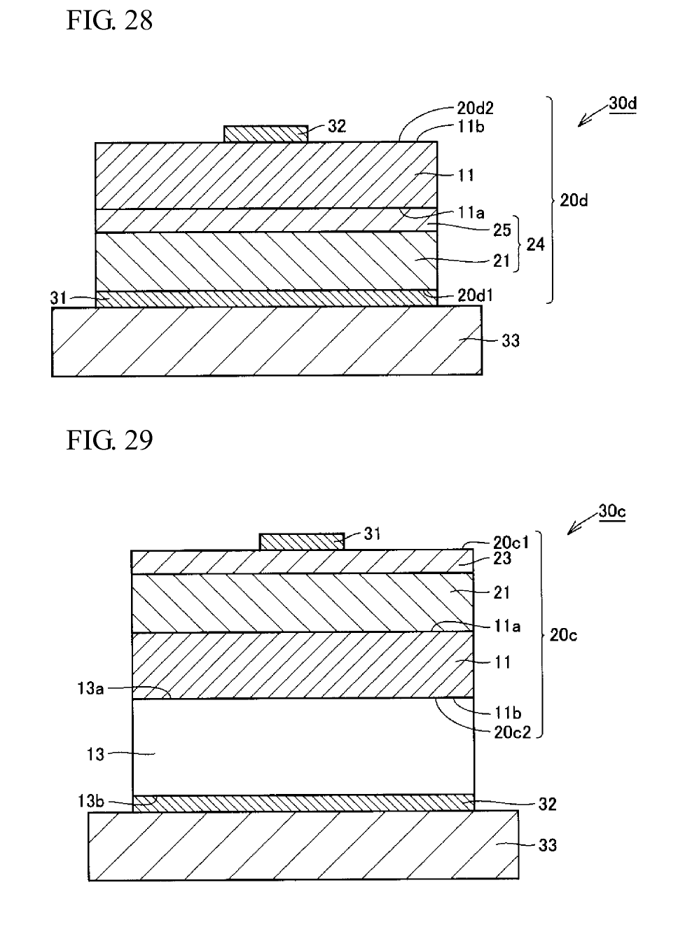

An infrared LED 30d in a modified example, as represented in FIG. 28, is furnished with basically the same structural makeup as that of an infrared LED 30a in Embodying Mode 6, but differs in utilizing an epitaxial wafer 20d of the modified example of Embodying Mode 4. This implementation enables an infrared LED 30a of improved V_{f} characteristics to be realized.

### Embodying Mode 7

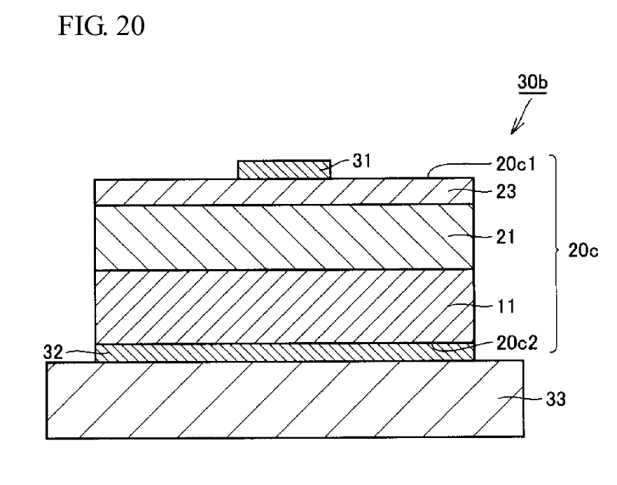

Referring to FIG. 20, an explanation of an infrared LED 30b in the present embodying mode will be made. As indicated in FIG. 20, an infrared LED 30b in the present embodying mode is furnished with basically the same structural makeup as an infrared LED 30a of Embodying Mode 6, but differs in that the wafer's AlₓGa₍₁₋ₓ₎As layer 11 side is disposed on the stem 33.

Specifically, the electrode 31 is provided contacting on the front side 20c1 of the epitaxial wafer 20c (on the contact layer 23 in the present embodying mode), while the electrode 32 is provided contacting on the back side 20c2 (on the AlₓGa₍₁₋ₓ₎As layer 11 in the present embodying mode).

The electrode 31 partially covers the front side 20c1 of the epitaxial wafer 20c, leaving the remaining area on the front side 20c1 of the epitaxial wafer 20c exposed in order for light to be extracted. The electrode 32, meanwhile, covers the entire surface of the back side 20c2 of the epitaxial wafer 20c.

A method of manufacturing an infrared LED 30b in the present embodying mode is furnished with the basically same constitution as the method of Embodying Mode 6 of manufacturing an infrared LED 30a, but as just described differs in Step S11 of forming the electrodes 31 and 32.

It should be understood that apart from the foregoing, the infrared LED 30b and its method of manufacture are otherwise of the same constitution as the infrared LED 30a and its method of manufacture in Embodying Mode 6; thus identical components are labeled with identical reference marks, and their explanation will not be repeated.

Further, in instances in which the GaAs substrate 13 has not been removed, an electrode may be formed on the reverse face of the GaAs substrate 13. With an epitaxial wafer 20a of Embodying Mode 3, in the case where an epitaxial wafer in which the epitaxial layer further including a contact layer is utilized to form an infrared LED, it will have a structure like, for example, infrared LED 30c illustrated in FIG. 29. In this case, as indicated in FIG. 29 as a representative example, the stem 33 is arranged on the GaAs substrate 13 side of the device. As a modified example of this, the GaAs substrate 13 side may be located on the opposite side of the device from that of the stem 33.

### Embodiment 1

In the present embodiment, the effect of, in an AlₓGa₍₁₋ₓ₎As layer 11, the amount fraction x of Al in the rear face 11b being greater than the amount fraction x of Al in the major surface 11a was investigated. Specifically, an AlₓGa₍₁₋ₓ₎As substrate 10a was manufactured in conformance with the AlₓGa₍₁₋ₓ₎As substrate 10a manufacturing method of Embodying Mode 1.

More particularly, GaAs substrates 13 were prepared (Step S1). Next, AlₓGa₍₁₋ₓ₎As layers 11 having a variety of Al amount fractions x 0≦x≦1 were grown by LPE onto the GaAs substrates 13 (Step S2).

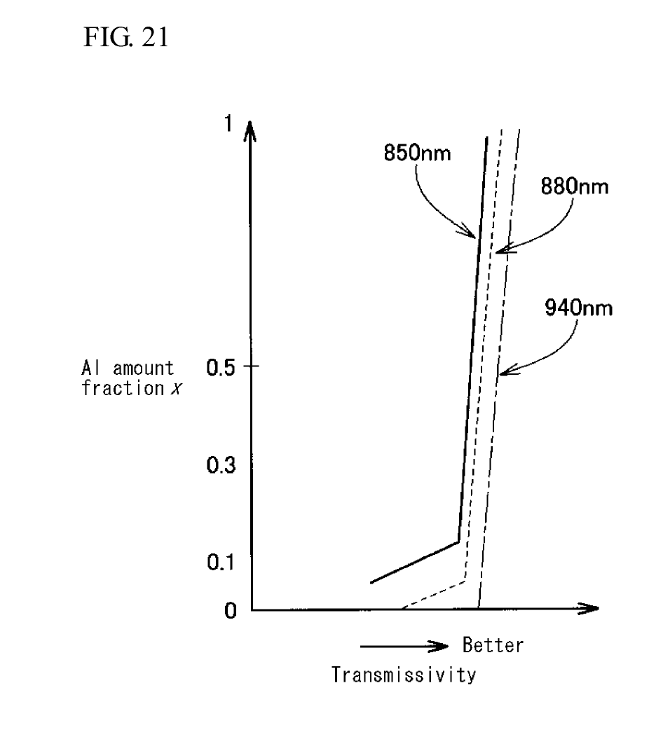

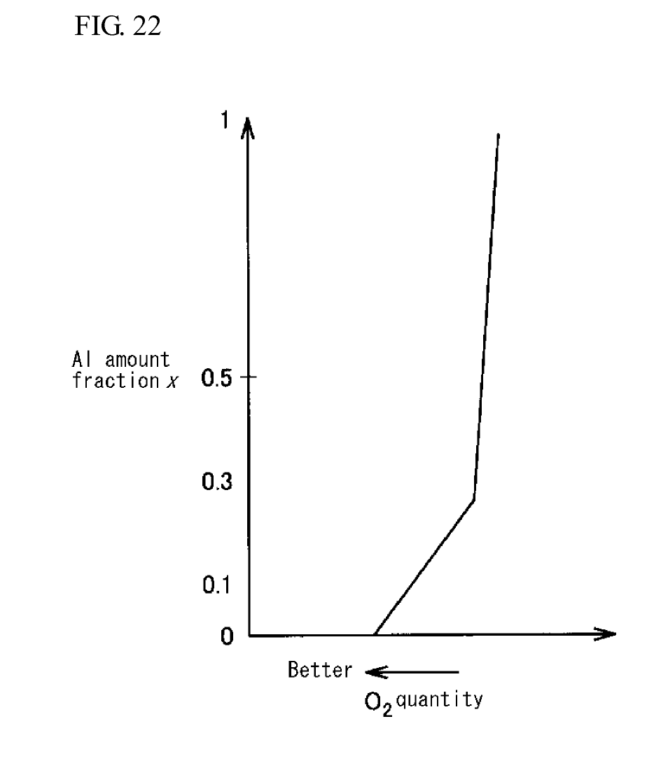

The transmissivity and surface oxygen quantity of the AlₓGa₍₁₋ₓ₎As layers 11 when their emission wavelength was 850 nm, 880 nm and 940 nm were examined. In order to check these characteristics: The AlₓGa₍₁₋ₓ₎As layer 11 of FIG. 1 was created at thicknesses of 80 μm to 100 μm, in such a way that the amount fraction of Al depth-wise would be uniform; the GaAs substrate 13 was removed as in the flow of FIG. 11; and with the layers in the FIG. 10 state, their transmissivity was measured with a transmittance meter. For the oxygen quantity: The same samples were created, in conformance with the flow in FIG. 14; epitaxial layers were grown by OMVPE; and, before the GaAs substrates 13 were removed, the major surface 11a of the AlₓGa₍₁₋ₓ₎As layers 11 was measured by secondary ion mass spectrometry (SIMS) characterization. The results are presented in FIG. 21 and FIG. 22.

In FIG. 21, the vertical axis indicates amount fraction x of Al in the AlₓGa₍₁₋ₓ₎As layers 11, while the horizontal axis indicates transmissivity. The further to the right is the position along the axis in FIG. 21, the better is the transmissivity. Also, from looking at the implementations with which emission wavelength was 880 nm, it was understood that the transmissivity is favorable even with lower Al amount fraction levels. Furthermore, the implementations with which the emission wavelength was 940 nm allowed it to be confirmed that even with lower Al amount fraction levels, deterioration in transmissivity was unlikely to occur.

Next, in FIG. 22, the vertical axis indicates amount fraction x of Al in the AlₓGa₍₁₋ₓ₎As layers 11, while the horizontal axis indicates surface oxygen quantity. The further to the left is the position along the axis in FIG. 22, the more favorable is the oxygen quantity. It will be understood that the surface oxygen quantity was the same when the emission wavelength was 850 nm, 880 nm and 940 nm.

Herein, in the present embodiment, as described above the AlₓGa₍₁₋ₓ₎As layers 11 were created in such a way that the Al amount fraction depth-wise would be uniform, yet it was confirmed, by the same experiment described earlier, that because the oxygen quantity is determined principally by the amount fraction of Al in the major surface 11a of the AlₓGa₍₁₋ₓ₎As layers 11, even in instances in which the layer possesses a gradient in Al amount fraction, as illustrated in FIG. 2 through FIG. 5, the oxygen quantity's correlation with the Al amount fraction in the major surface is strong.

The same tendency holds true with respect to the transmissivity: In instances in which the layer possesses a gradient in Al amount fraction as illustrated in FIG. 2 through FIG. 5, the transmissivity is affected by the area where the Al amount fraction is lowest. Specifically, in implementations possessing a gradient as illustrated in FIG. 2 through FIG. 5, if the pattern of the gradient (layer number, gradient in each layer, thickness) and the gradient (ΔAl/distance) are the same, the correlation of the transmissivity to the size of the average Al amount fraction within the layer is strong.

It was recognized that, as shown in FIG. 21, the greater is the amount fraction x of Al in the AlₓGa₍₁₋ₓ₎As layer 11, the more the transmissivity improves. Likewise, it was recognized that, as shown in FIG. 22, the lower is the amount fraction x of Al in the AlₓGa₍₁₋ₓ₎As layer 11, the more the oxygen quantity contained in the major surface may be reduced.

From the foregoing, it was understood that according to the present embodiment, in the AlₓGa₍₁₋ₓ₎As layers 11, raising the amount fraction x of Al in the rear face 11b maintains a high level of transmissivity, while lowering the amount fraction x of Al in the major surface 11a allows the oxygen quantity in the major surface to be reduced.

### Embodiment 2

In the present embodiment, the effect of an AlₓGa₍₁₋ₓ₎As layer 11 being furnished with a plurality of layers in each of which the amount fraction x of Al heading from the plane of the layer's rear face 11b side to the plane of its major surface 11a side monotonically decreases was investigated. Specifically, thirty-two different samples of AlₓGa₍₁₋ₓ₎As substrate 10a were manufactured in conformance with the method of manufacturing the AlₓGa₍₁₋ₓ₎As substrate 10a, depicted FIG. 1, in Embodying Mode 1.

More particularly, 2-inch and 3-inch GaAs substrates 13 were prepared (Step S1).

Next, AlₓGa₍₁₋ₓ₎As layers 11 were grown by a slow-cooling technique (Step S2). In Step S2, the layers were grown so as to contain one or more laminae in each of which, as diagrammed in FIG. 2, the amount fraction x of Al constantly decreased heading in the growth direction. In detail, thirty-two different samples of AlₓGa₍₁₋ₓ₎As layer 11 were grown in which the following parameters were as entered in the table below: the Al amount fraction x in the major surface 11a of the AlₓGa₍₁₋ₓ₎As layer 11 (minimum value of Al amount fraction x); in each lamina, the difference between the Al amount fraction x in the plane of the layer's rear face 11b side and the Al amount fraction x in the plane of its major surface 11a side (difference in Al amount fraction x); and number of laminae in each of which the amount fraction x of Al heading from the plane of the layer's rear face 11b side to the plane of its major surface 11a side monotonically decreased (laminae number). Thirty-two different samples of AlₓGa₍₁₋ₓ₎As substrate 10a were thereby manufactured.

With regard to the AlₓGa₍₁₋ₓ₎As substrates 10a themselves, warp appearing in an AlₓGa₍₁₋ₓ₎As substrate 10a—the gap between the AlₓGa₍₁₋ₓ₎As substrate 10a with its convexly deviating surface face up, and a planar block—was measured by employing a thickness gauge. The results are tabulated in Table I below. In Table I, instances in which warp occurring in an AlₓGa₍₁₋ₓ₎As substrate 10a was 200 μm or less when a 2-inch GaAs substrate was used, and was 300 μm or less when a 3-inch GaAs substrate was used are designated “∘,” while instances in which warp exceeded 200 μm when a 2-inch GaAs substrate was used, and exceeded 300 μm when a 3-inch GaAs substrate was used are designated “×.”

TABLE I

| Minimum | Al amount | Warp for each number of laminae | | | |
|---|---|---|---|---|---|
| Al amount | fraction x | 1 | 2 | 3 | 4 |
| fraction x | difference | lamina | laminae | laminae | laminae |
| 0.1 to 0.3 | 0 ≦ x < 0.15 | ∘ | ∘ | ∘ | ∘ |
| | 0.15 ≦ x < 0.25 | x | ∘ | ∘ | ∘ |
| | 0.25 ≦ x < 0.35 | x | x | ∘ | ∘ |
| | 0.35 ≦ x | x | x | x | x |
| 0.3 to 0.5 | 0 ≦ x < 0.15 | ∘ | ∘ | ∘ | ∘ |
| | 0.15 ≦ x < 0.25 | x | ∘ | ∘ | ∘ |
| | 0.25 ≦ x < 0.35 | x | x | ∘ | ∘ |
| | 0.35 ≦ x | x | x | x | x |

As is evident from Table I, regardless of the Al amount fraction x in the major surface 11a, the smaller the difference in Al amount fraction x within the laminae where it monotonically decreases, the less likely warp was to occur in the AlₓGa₍₁₋ₓ₎As substrates 10a. It was understood that in instances in which the difference in Al amount fraction x was 0.15 or greater, but less than 0.35, warp could be mitigated by the AlₓGa₍₁₋ₓ₎As layer 11 including numerous laminae with the monotonically decreasing amount fraction. From this result, it was inferred that in instances in which the difference in Al amount fraction x was a small 0.15 or less, increasing the number of laminae with the monotonically decreasing amount fraction would be efficacious if warp was to be further reduced. It was likewise inferred that in instances in which the difference in Al amount fraction x was 0.35 or greater, increasing to five or more the number of laminae in which x monotonically decreased would allow warp to be mitigated. It should be noted that there were no special differences between using 2-inch and 3-inch GaAs substrates.

As described in the foregoing, the present embodiment let it be confirmed that warp in the AlₓGa₍₁₋ₓ₎As substrates 10a can be mitigated by the AlₓGa₍₁₋ₓ₎As layer 11 including a plurality of laminae in each of which the amount fraction x of Al heading from the plane of the layer's rear face 11b side to the plane of its major surface 11a side monotonically decreases.

### Embodiment 3

In the present embodiment, the effect of an infrared-LED epitaxial wafer being furnished with an active layer having a multiquantum-well structure, as well as a satisfactory laminae number for the barrier layers and the well layers was investigated.

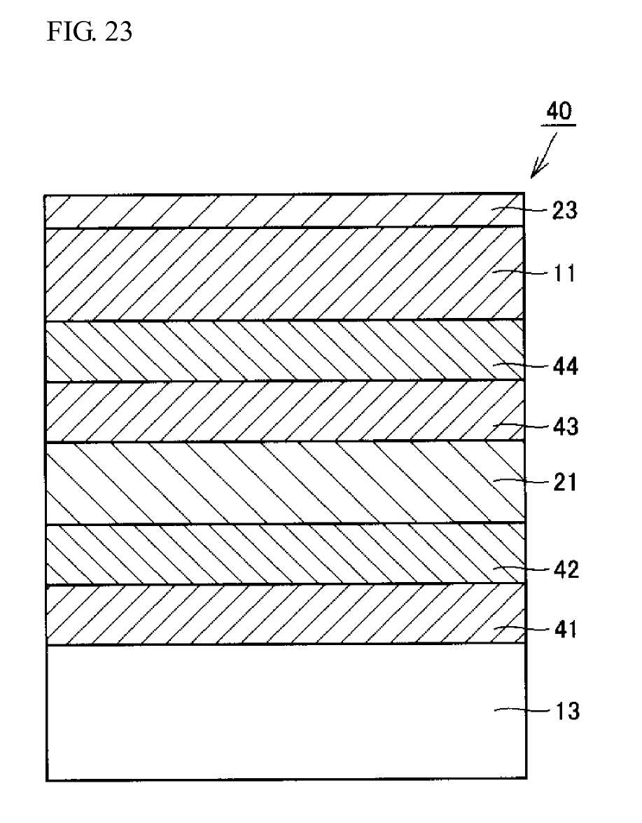

In the present embodiment, four different samples, indicated in FIG. 23, of epitaxial wafers 40 were grown in which only the thickness of, and number of laminae in, the multiquantum-well-structure active layer 21 were varied.

Specifically, to begin with, GaAs substrates 13 were prepared (Step S1). Next, by OMVPE, an n-type cladding layer 41, an undoped guide layer 42, an active layer 21, an undoped guide layer 43, a p-type cladding layer 44, an AlₓGa₍₁₋ₓ₎As layer 11, and a contact layer 23 were grown, in that order. The growth temperature for each layer was 750° C. The n-type cladding layers 41 had a thickness of 0.5 μm and consisted of Al_{0.35}Ga_{0.65}As; the undoped guide layers 42 had a thickness of 0.02 μm and consisted of Al_{0.30}Ga_{0.70}As; the undoped guide layers 43 had a thickness of 0.02 μm and consisted of Al_{0.30}Ga_{0.70}As; the p-type cladding layers 44 had a thickness of 0.5 μm and consisted of Al_{0.35}Ga_{0.65}As; the AlₓGa₍₁₋ₓ₎As layers 11 had a thickness of 2 μm and consisted of p-type Al_{0.15}Ga_{0.85}As; and the contact layers 23 had a thickness of 0.01 μm and consisted of p-type GaAs. Furthermore, the active layers 21 were made to have optical emission wavelengths of from 840 nm to 860 nm, and were multiquantum-well (MQW) structures having two laminae, ten laminae, twenty laminae and fifty laminae of well layers and barrier layers, respectively. The well layers each had a thickness of 7.5 nm and consisted of GaAs, while the barrier layers each were laminae having a thickness of 5 nm and consisting of Al_{0.30}Ga_{0.70}As.

In addition, in the present embodiment a double-heterostructure epitaxial wafer, differing only in being furnished with an active layer composed solely of well layers whose emission wavelength was 870 nm and having a thickness of 0.5 μm, was grown as a separate epitaxial wafer for infrared LEDs.

As far as the respective grown epitaxial wafers are concerned, the epitaxial wafers were each manufactured without removing the GaAs substrate. Next, onto the contact layer 23, an electrode consisting of AuZn, and onto the n-type GaAs substrate 13, an electrode consisting of AuGe were respectively formed by vapor deposition. Infrared LEDs were thereby obtained.

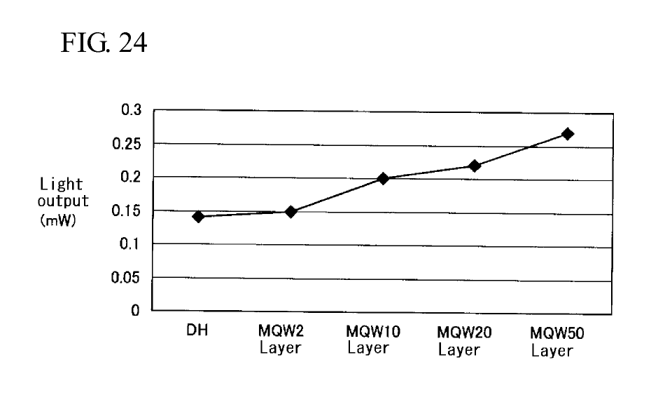

The light output of each infrared LED when a current of 20 mA was passed through it was measured with a constant-current source and a photometric instrument (integrating sphere). The results are diagrammed in FIG. 24. It should be noted that “DH” along the horizontal axis in FIG. 24 denotes an LED having a double heterostructure, “MQW” denotes LEDs furnished with well layers and barrier layers in an active layer, and the layer number denotes the laminae count of the well layers and of the barrier layers, respectively.

It was found that, as indicated in FIG. 24, compared with the LED having a double heterostructure, the LEDs furnished with an active layer having a multiquantum-well structure allowed the light output to be improved. In particular, it was understood that the LEDs with between ten and fifty well layers and barrier layers (both inclusive) led to dramatically improved light output.

Herein, in the present embodiment, the AlₓGa₍₁₋ₓ₎As layers 11 were produced by OMVPE, but OMVPE requires an extraordinary amount of time in order to grow the AlₓGa₍₁₋ₓ₎As layers 11 if their thickness is to be as great as in cases such as Embodiment 1. This point aside, the characteristics of the infrared LEDs created are the same as those of present-invention infrared LEDs wherein LPE and OMVPE were utilized, and thus for infrared LEDs of the present invention they do apply. It should be noted that in implementations in which the AlₓGa₍₁₋ₓ₎As layer 11 thickness is large, utilizing LPE demonstrates the effect of making it possible to shorten the time needed in order to grow the AlₓGa₍₁₋ₓ₎As layer 11.

In addition, in the present embodiment, as still another epitaxial wafer for infrared LEDs, epitaxial wafers of multiquantum-well structure (MQW), differing only in that their emission wavelength was 940 nm and in being furnished with an active layer containing well layers having InGaAs in the well laminae, were grown. With the InGaAs of the well laminae, the thickness was 2 nm to 10 nm and the amount fraction of In consisted of 0.1 to 0.3. Meanwhile, the barrier layers consisted of Al_{0.30}Ga_{0.70}As.

Onto these epitaxial wafers also, in the same way as described above, electrodes were formed to create infrared LEDs. As to these infrared LEDs as well, the light output power was characterized in the same way as described above, with the result that light output powers whose emission wavelength was 940 nm were obtained.

Here, with respect to the barrier layers it has been confirmed by experimentation that even if they are anywhere from GaAs_{0.90}P_{0.10} to Al_{0.30}Ga_{0.70}As_{0.90}P_{0.10} they will have similar results. Further, the fact that the amount fraction of In and the amount fraction of P are adjustable at will has been confirmed by experimentation.

The foregoing allowed confirmation of utilizing as the active layer MQWs, with the well laminae being GaAs, in implementations in which the emission wavelength is to be between 840 nm and 890 nm both inclusive, and that a double heterostructure (DH) constituted by GaAs is applicable to implementations in which the emission wavelength is to be between 860 nm and 890 nm both inclusive. In addition, it could be confirmed that in implementations in which the emission wavelength is to be between 850 nm and 1100 nm both inclusive, it is possible to create the active layer from well layers constituted by InGaAs.

### Embodiment 4

In the present embodiment, the effective range of thickness of the AlₓGa₍₁₋ₓ₎As layer 11 in epitaxial wafers for infrared LEDs was investigated.

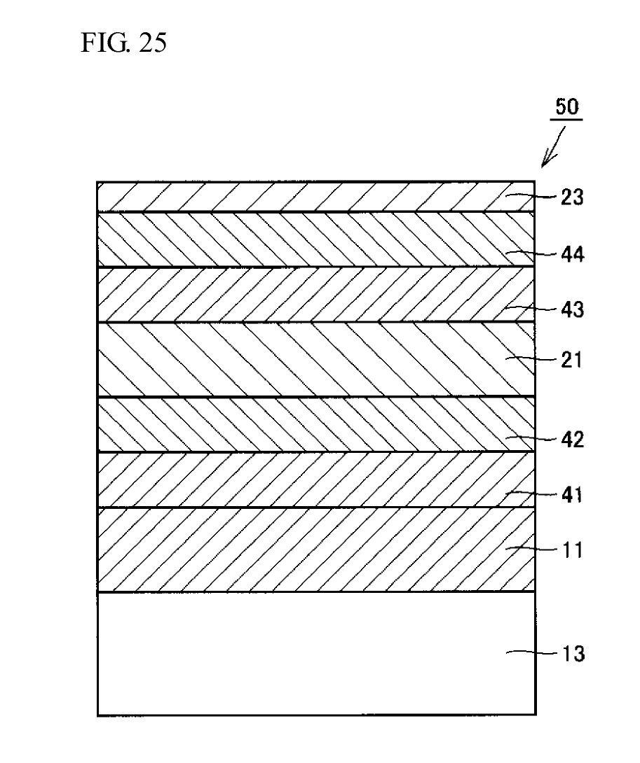

In the present embodiment, five different samples, indicated in FIG. 25, of epitaxial wafers 50 were grown in which only the thickness of the AlₓGa₍₁₋ₓ₎As layer 11 was varied.

Specifically, to begin with, GaAs substrates 13 were prepared (Step S1). Next, by LPE, AlₓGa₍₁₋ₓ₎As layers 11 having thicknesses of 2 μm, 10 μm, 20 μm, 100 μm, and 140 μm, and constituted from p-type Al_{0.35}Ga_{0.65}As doped with Zn were respectively formed (Step S2). The LPE growth temperature at which the AlₓGa₍₁₋ₓ₎As layers 11 were grown was 780° C., and the growth rate was an average 4 μm/h. Next, using hydrochloric acid and sulfuric acid, the major surface 11a of the AlₓGa₍₁₋ₓ₎As layers 11 was washed (Step S3). Then major surface 11a of the AlₓGa₍₁₋ₓ₎As layers 11 was polished by means of chemical-mechanical planarization (Step S4). The major surface 11a of the AlₓGa₍₁₋ₓ₎As layers 11 was then washed using ammonia and hydrogen peroxide (Step S5). Next, by OMVPE, a p-type cladding layer 41, an undoped guide layer 42, an active layer 21, an undoped guide layer 43, an n-type cladding layer 44, and an n-type contact layer 23 were grown, in that order (Step S6). The OMVPE growth temperature for growing these layers was 750° C., while the growth rate was 1 to 2 μm/h. Here the thicknesses and the materials (apart from the dopants) for the p-type cladding layer 41, the undoped guide layer 42, the undoped guide layer 43, the n-type cladding layer 44, and the n-type contact layer 23 were made the same as in Embodiment 3. Furthermore, active layers 21 having twenty laminae each of well layers and barrier layers were grown. The well layers each had a thickness of 7.5 nm and consisted of GaAs, while the barrier layers each were laminae having a thickness of 5 nm and consisting of Al_{0.30}Ga_{0.70}As.

Next, the GaAs substrate 13 was removed (Step S7). Infrared-LED epitaxial wafers furnished with AlₓGa₍₁₋ₓ₎As layers having five different thicknesses were thereby manufactured.

Next, onto the contact layer 23, an electrode consisting of AuGe, and onto the rear face 11b of the AlₓGa₍₁₋ₓ₎As layer 11, an electrode consisting of AuZn were respectively formed by vapor deposition. Infrared LEDs were thereby manufactured.

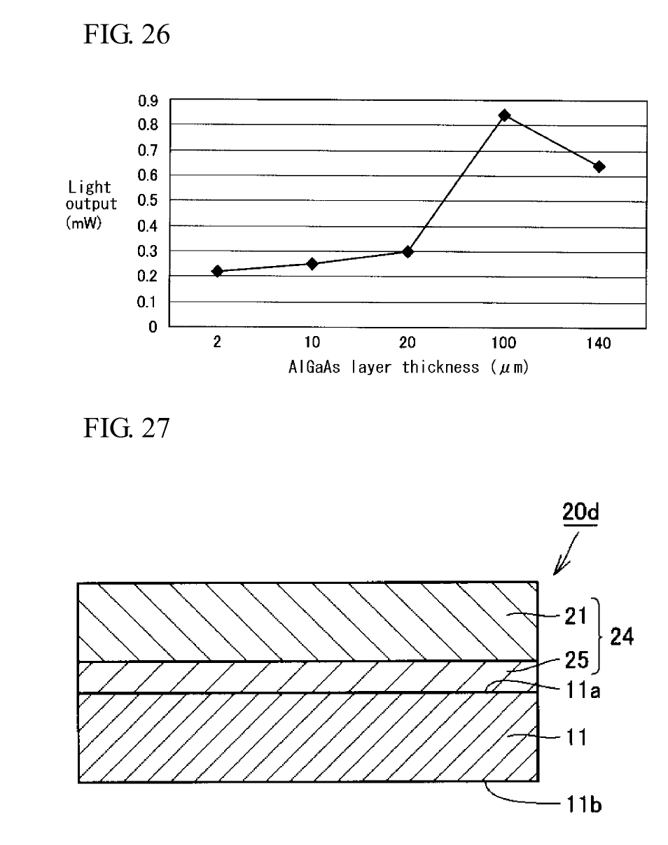

The light output of each of the infrared LEDs was measured in the same way as in Embodiment 3. The results are diagrammed in FIG. 26.

As indicated in FIG. 26, infrared LEDs furnished with an AlₓGa₍₁₋ₓ₎As layer 11 having a thickness of between 20 μm and 140 μm both inclusive made it possible to improve light output significantly, while infrared LEDs furnished with an AlₓGa₍₁₋ₓ₎As layer 11 having a thickness of between 100 μm and 140 μm both inclusive made possible extraordinary improvement in light output.

Now, with layer thicknesses under 20 μm, the fact that effectiveness from the GaAs 13 substrate having been removed was not seen is believed, from luminescent image observations, to be because there was hardly any change in the extent of the emission surface area. That is because on account of the low mobility with a Zn-doped p-type AlₓGa₍₁₋ₓ₎As layer 11, current does not diffuse. This can be remedied by having it be a Te-doped n-type AlₓGa₍₁₋ₓ₎As layer 11 to raise the mobility. In below-described Embodiment 5, making the layers Te-doped was seen to broaden the luminescent image, improving the light output.

### Embodiment 5

In the present embodiment, the effects from the fact that active-layer directed dispersion as caused by infrared LEDs of the present invention is low were investigated.

### Sample 1

A Sample 1 epitaxial wafer for infrared LEDs was manufactured as follows. Specifically, at first a GaAs substrate 13 was prepared (Step S1). Next, by LPE, a Te-doped AlₓGa₍₁₋ₓ₎As layer 11 having a thickness of 20 μm and constituted from n-type Al_{0.35}Ga_{0.65}As was grown (Step S2). Next, hydrochloric acid and sulfuric acid were employed to wash the major surface 11a of the AlₓGa₍₁₋ₓ₎As layer 11 (Step S3). Subsequently, the major surface 11a of the AlₓGa₍₁₋ₓ₎As layer 11 was polished by means of chemical-mechanical planarization (Step S4). Ammonia and hydrogen peroxide were employed then to wash the major surface 11a of the AlₓGa₍₁₋ₓ₎As layer 11 (Step S5). Next, by OMVPE, an Si-doped n-type cladding layer 41, an undoped guide layer 42, an active layer 21, an undoped guide layer 43, a Zn-doped p-type cladding layer 44, and a p-type contact layer 23 were grown, in that order (Step S6), as illustrated in FIG. 25. Here the thicknesses of, and the materials apart from the dopants for, the n-type cladding layer 41, the undoped guide layer 42, the undoped guide layer 43, and the p-type cladding layer 44 were made the same as in Embodiment 3. In addition, an active layer 21 having twenty laminae each of well layers and barrier layers was grown. The well layers each were laminae having a thickness of 7.5 nm and consisting of GaAs, while the barrier layers each were laminae having a thickness of 5 nm and consisting of Al_{0.30}Ga_{0.70}As. Also, the growth temperatures and growth rates in the LPE and OMVPE were made the same as in Embodiment 4.

The GaAs substrate 13 was then removed (Step S7). A Sample 1 infrared-LED epitaxial wafer was thereby manufactured.

Next, onto the p-contact layer 23, an electrode consisting of AuZn, and onto the bottom of the AlₓGa₍₁₋ₓ₎As layer 11, an electrode consisting of AuGe were respectively formed by vapor deposition (Step S11). An infrared LED was thereby manufactured.

### Sample 2

For Sample 2, to begin with a GaAs substrate 13 was prepared (Step S1). Next, by OMVPE, a p-type cladding layer 44, an undoped guide layer 43, an active layer 21, an undoped guide layer 42, and an n-type cladding layer 41 were grown, in that order, in the same manner as with Sample 1. Next, an AlₓGa₍₁₋ₓ₎As layer 11 was formed by LPE. The thickness of and material constituting the AlₓGa₍₁₋ₓ₎As layer 11 was made the same as with Sample 1.

Next, likewise as with Sample 1, the GaAs substrate 13 was removed, producing a Sample 2 infrared-LED epitaxial wafer.

Next, electrodes were formed onto the front and back sides of the epitaxial wafer in the same manner as with Sample 1, producing a Sample 2 infrared LED.

### Measurement Method

The Zn diffusion length in, and the light output from, the infrared LEDs of Samples 1 and 2 were measured. Specifically, the Zn concentration in the interface between the active layer and the guide layers was characterized by SIMS, and additionally, the position in the active layer where the Zn concentration fell to 1/10 or less was measured by SIMS, and the distance into the active layer from the interface between the active layer and the guide layers was taken as the Zn diffusion length. Here too the light output was measured in the same way as in Embodiment 3. The results are set forth in Table II below.

TABLE II

| | Zn diffusion | Zn max. conc. inside | Light |
|---|---|---|---|
| | length (μm) | active layer (cm⁻³) | output (mW) |
| Pres. invent. ex. | 0 | 6.0 × 10¹⁵ | 1.3 |
| Comp. ex. | 0.3 | 6.0 × 10¹⁷ | 0.62 |

### Measurement Results

As indicated in Table II, with Sample 1, in which the active layer was grown by OMVPE after the AlₓGa₍₁₋ₓ₎As layer 11 had been grown by LPE, the Zn doped into the AlₓGa₍₁₋ₓ₎As 11, formed ahead of the active layer, could be prevented from diffusing inside the active layer, and the Zn concentration within the active layer 21 could be reduced. As a result, the light output from the Sample 1 infrared LED could be dramatically improved over that from Sample 2.

The foregoing allowed it to be confirmed that in accordance with the present invention, forming the active-layer-incorporating epitaxial layer (Step S7) after the AlₓGa₍₁₋ₓ₎As layer 11 has been formed by LPE (Step S2) enables the light output to be improved.

### Embodiment 6

In the present embodiment, the effect of ΔAl/Δt being greater than 0/μm was investigated.

Specifically, GaAs substrates were prepared (Step S1). Next, by a slow-cooling technique AlₓGa₍₁₋ₓ₎As layers 11 having various thicknesses and amount fractions x of Al were grown (Step S2).

In Step S2, the layers were grown so as to contain one or more laminae in each of which the Al amount fraction x continually decreased heading in the growth direction. Next, washing, polishing, and washing steps (Steps S3 through S5) were followed to fabricate AlₓGa₍₁₋ₓ₎As substrates on which a GaAs substrate was formed. Next, onto the major surface 11a of the AlₓGa₍₁₋ₓ₎As layers 11, an active layer 21 was formed by OMVPE (Step S7). The GaAs substrates were then removed (Step S6). A plurality of epitaxial wafers were thereby manufactured.

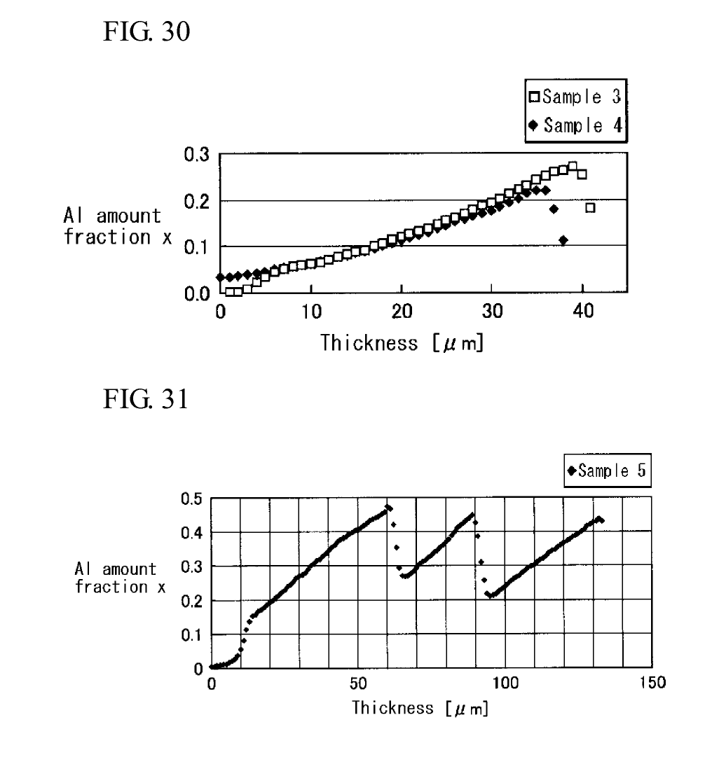

In these epitaxial wafers in cross section, at 1 μm intervals heading from the rear face of the AlₓGa₍₁₋ₓ₎As substrates to their major surface, the amount fraction x of Al was determined with an EPMA. The results with Samples 3 and 4, in which the layer in which the Al amount fraction x continuously decreased heading the growth direction had a single lamina, and with Sample 5, in which the layer in which the Al amount fraction x continuously decreased heading the growth direction had three laminae are diagrammed in FIGS. 30 and 31. It should be noted that in FIGS. 30 and 31, thickness “0” along the horizontal axis corresponds to the rear-face side of the AlₓGa₍₁₋ₓ₎As substrate.

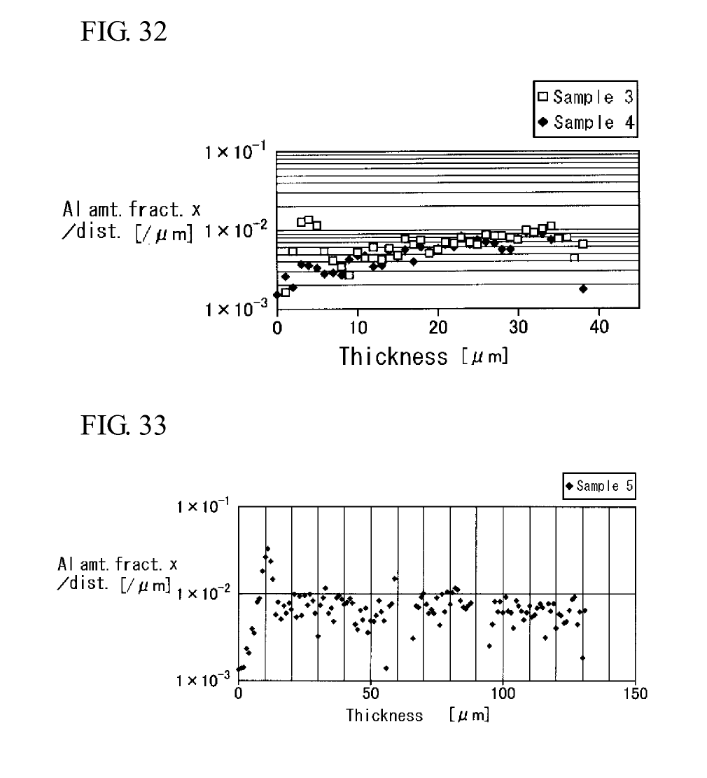

As indicated in FIGS. 30 and 31, for the AlₓGa₍₁₋ₓ₎As substrates in which the amount fraction x of Al was determined, ΔAl/Δt (units: amount fraction difference/μm), which is the slope of the Al amount fraction, was found. The results are plotted in FIGS. 32 and 33. It will be understood that in FIGS. 32 and 33, the rear face of the AlₓGa₍₁₋ₓ₎As substrates is taken to be thickness 0.

ΔAl/Δt for either Sample 3 or Sample 4 graphed in FIG. 32 was from 1×10⁻³/μm to 2×10⁻²/μm. ΔAl/Δt for Sample 5 graphed in FIG. 33 was from 1×10⁻³/μm to 3×10⁻²/μm.

In this way, ΔAl/Δt for a plurality of AlₓGa₍₁₋ₓ₎As substrates apart from Samples 3 through 5 was likewise determined.

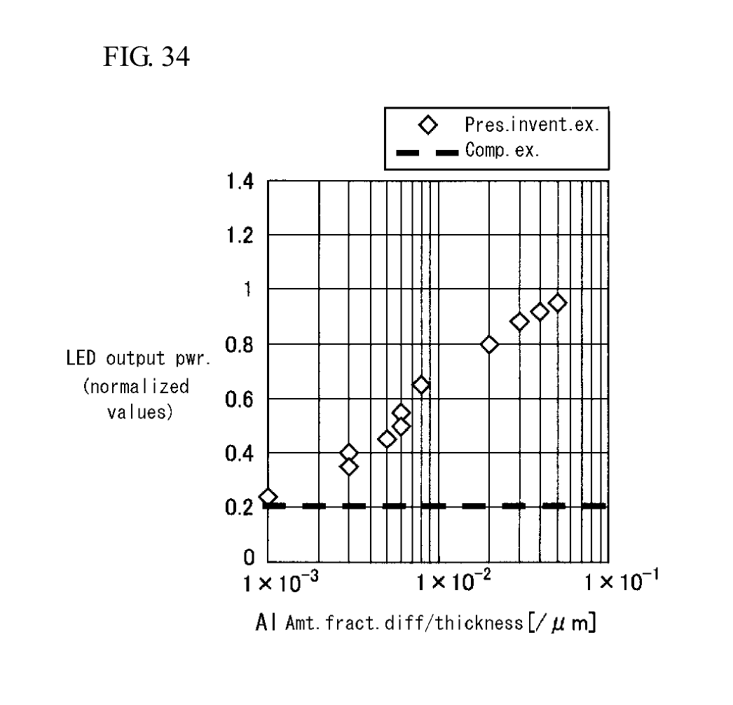

Thereafter, the epitaxial wafers furnished with the AlₓGa₍₁₋ₓ₎As substrates were diced into LED chips 400 μm square. Then the light output from these LEDs at 20 mA/chip was determined, and normalized with a reference output. The results when the average Al amount fraction x in the AlₓGa₍₁₋ₓ₎As layer 11 was 0≦x≦0.3, when it was 0.3≦x≦0.5, and when it was 0.5≦x≦1.0 are diagrammed in FIGS. 34 through 36, respectively.

Meanwhile, as comparative examples, AlₓGa₍₁₋ₓ₎As substrates consisting of AlₓGa₍₁₋ₓ₎As layers 11 in which the amount fraction x of Al was constant at 0.1, 0.3 and 0.5 were prepared, epitaxial layers were grown in the same way onto the AlₓGa₍₁₋ₓ₎As substrates, and the articles were diced into LED chips. These LEDs were likewise normalized with the reference output, and the respective results are plotted as comparative examples in FIGS. 34 through 36.

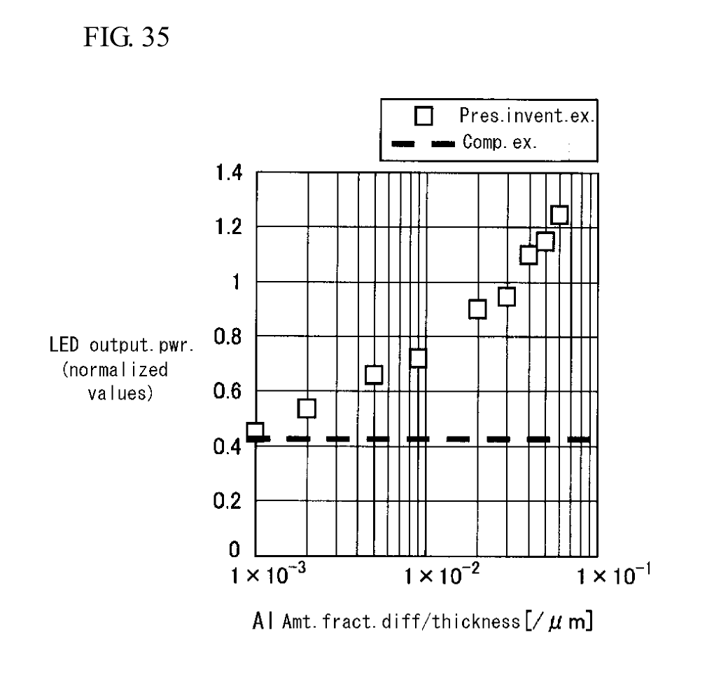

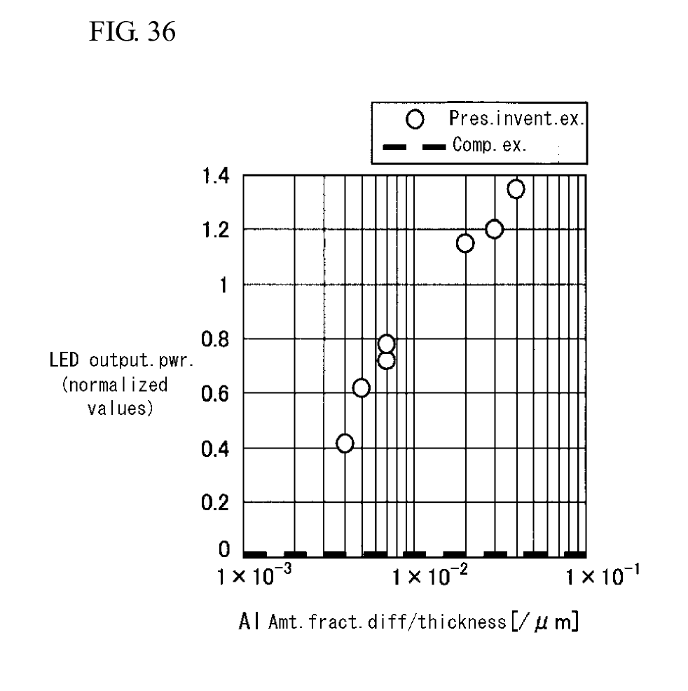

The Al amount fraction for the comparative example in FIG. 34 was 0.1; the Al amount fraction for the comparative example in FIG. 35 was 0.3; and the Al amount fraction for the comparative example in FIG. 36 is 0.5. It will be appreciated that while ΔAl/Δt for the comparative examples is 0, for the sake of comparison, the reference output for the comparative examples in FIGS. 34 through 36 is indicated by the dashed line.

As indicated in FIGS. 34 through 36, compared with implementations in which the amount fraction x of Al was constant, from the present invention examples, in which ΔAl/Δt exceeded 0, improved output was possible.

In addition, as indicated in FIG. 34, with the instances in which the Al amount fraction was low (0≦x≦0.3) the output was unlikely to rise overall, owing to the low transmissivity, whereas ΔAl/Δt growing larger had a striking effect in that the transmissivity rose.

And as indicated in FIG. 36, with the instances in which the Al amount fraction was high (0.5≦x≦1.0), in the comparative example implementations, in which the amount fraction was constant, because the major surface of the AlₓGa₍₁₋ₓ₎As layer oxidized output was unobtainable. Nevertheless, the implementations in which the Al amount fraction was high but ΔAl/Δt exceeded 0, the major surface could be kept from being oxidized and output could be improved.

With the instances diagrammed in FIG. 35, in which the Al amount fraction was intermediate between that of FIGS. 34 and 36 (0.3≦x≦0.5), even in the implementation in which the Al amount fraction was constant (0.3), improvement over the comparative examples in which the Al amount fraction was constant at 0.1 and 0.5 was possible. Nevertheless, the present invention examples, in which ΔAl/Δt exceeded 0, allowed the output to be improved even over the comparative example in which the Al amount fraction was 0.3.

From the foregoing it could be confirmed that according to the present embodiment, ΔAl/Δt exceeding 0 enabled the output to be improved.

It could also be confirmed that the output could be improved the larger that ΔAl/Δt was. In the present embodiment, as indicated in FIG. 35, it was possible to manufacture an AlₓGa₍₁₋ₓ₎As substrate in which ΔAl/Δt was up to 6×10⁻²/μm.

It could further be confirmed that the amount fraction x of Al being more than 0.3 but less than or equal to 1 enabled the output to be improved extraordinarily.

### Embodiment 7

In the present embodiment, the effect of the peak oxygen concentration at the interface between the AlₓGa₍₁₋ₓ₎As layer and the epitaxial layer being not greater than 5×10²⁰ atoms/cm³, and the effect of the planar density of oxygen being not greater than 2.5×10¹⁵ atoms/cm² were investigated.

Specifically, GaAs substrates were prepared (Step S1). Next, by a slow-cooling technique AlₓGa₍₁₋ₓ₎As layers 11 were grown under various conditions (Step S2). In Step S2, the layers were grown so as to contain one lamina in which the Al amount fraction x continually decreased heading in the growth direction. Meanwhile, the thickness of the AlₓGa₍₁₋ₓ₎As layers 11 was 3.6 μm. Eight different AlₓGa₍₁₋ₓ₎As substrates were thereby manufactured.

Next, an active layer 21 was formed by OMVPE onto the major surface 11a of the AlₓGa₍₁₋ₓ₎As layers 11 (Step S7). The thickness of the active layers 21 was 0.6 μm. Eight different epitaxial wafers were thereby manufactured.

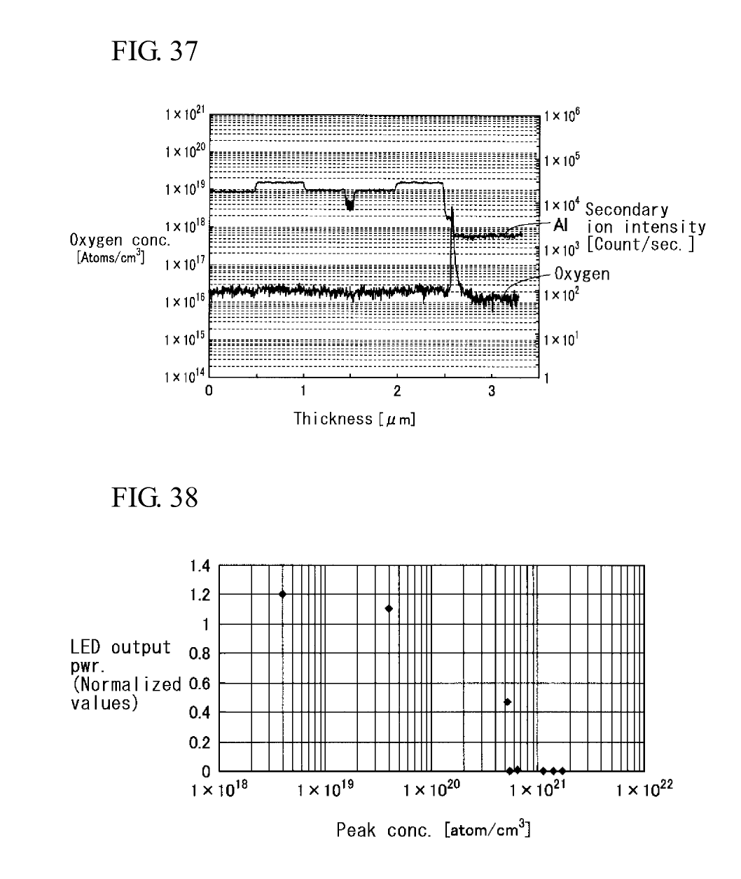

The results of characterizing oxygen concentration and secondary-ion intensity by SIMS in one of the epitaxial wafers are given in FIG. 37. In FIG. 37, the horizontal axis, with “0” taken as the surface of the active layer, is the thickness (units: μm) heading from the surface of the active layer to the rear face of the AlₓGa₍₁₋ₓ₎As layer. The point where the Al concentration and the oxygen concentration intersect is the interface between the AlₓGa₍₁₋ₓ₎As layer and the epitaxial layer. In the epitaxial wafer of FIG. 37, the peak oxygen concentration at the interface between the AlₓGa₍₁₋ₓ₎As layer and the epitaxial layer (at the major surface of the AlₓGa₍₁₋ₓ₎As layer) was 3×10¹⁸ atoms/cm³.

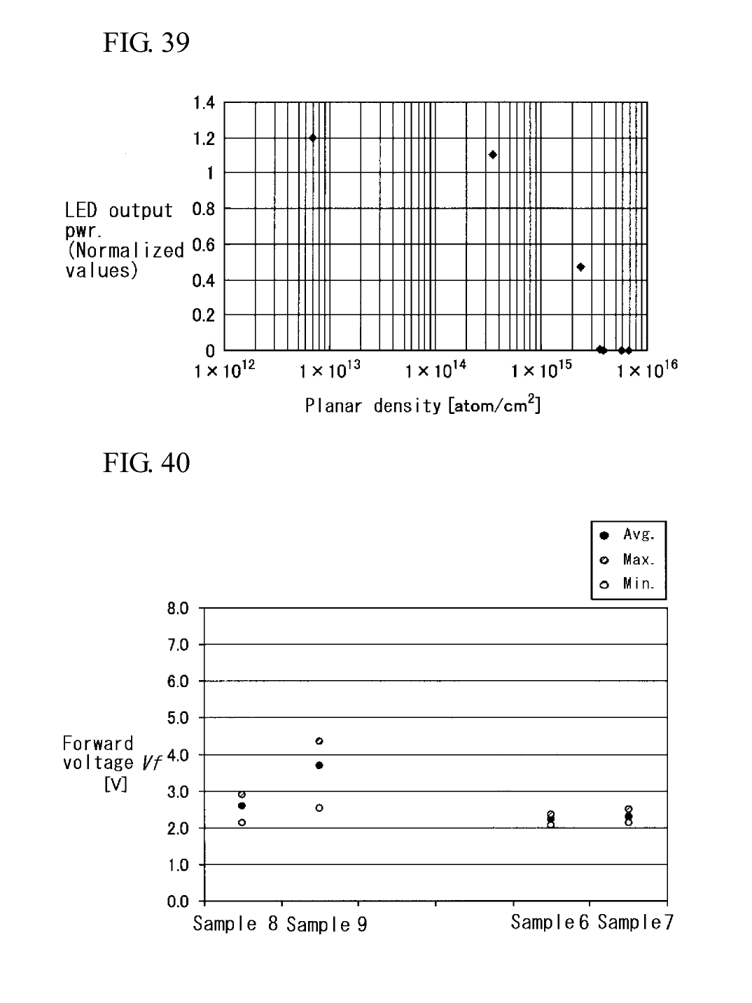

In this way, the oxygen concentration and secondary-ion intensity of the eight different epitaxial wafers were determined. Then, by finding the peak concentration among the oxygen concentrations, in respect of the eight different epitaxial wafers, the peak concentration of oxygen at the interface between the AlₓGa₍₁₋ₓ₎As layer and the epitaxial layer—that is, in the major surface of the AlₓGa₍₁₋ₓ₎As layer—was determined. In addition, by finding the planar density from the secondary-ion intensity and the thickness, the planar density of oxygen at the interface between the AlₓGa₍₁₋ₓ₎As layer and the epitaxial layer—that is, in the major surface of the AlₓGa₍₁₋ₓ₎As layer—was determined for each of the eight different epitaxial wafers. The results are given in FIGS. 38 and 39.

Thereafter, the epitaxial wafers furnished with the AlₓGa₍₁₋ₓ₎As substrates were diced into LED chips 400 μm square. Then the light output from these LEDs at 20 mA/chip was determined, and normalized with a reference output. The results are given in FIGS. 38 and 39.

As indicated in FIG. 38, in the implementations in which the oxygen peak concentration in the major surface of the AlₓGa₍₁₋ₓ₎As layer exceeded 5×10²⁰ atoms/cm³, output essentially was unobtainable. In the implementations, however, in which the oxygen peak concentration was not more than 5×10²⁰ atoms/cm³, output was obtainable. In particular, in the instances where the concentration was not greater than 4×10¹⁹ atoms/cm³, the output exceeded 1, wherein the output could be exceptionally improved.

Likewise, as indicated in FIG. 39, in the implementations in which the planar oxygen density in the major surface of the AlₓGa₍₁₋ₓ₎As layer exceeded 2.5×10¹⁵ atoms/cm², output essentially was unobtainable. In the implementations, however, in which the planar oxygen density was not more than 2.5×10¹⁵ atoms/cm², output was obtainable. In particular, in the instances where the density was not greater than 3.5×10¹⁴ atoms/cm², the output exceeded 1, wherein the output could be exceptionally improved.

From the foregoing it could be confirmed that according to the present embodiment, the peak oxygen concentration at the interface between the AlₓGa₍₁₋ₓ₎As layer and the epitaxial layer being not greater than 5×10²⁰ atoms/cm³, and the planar density of oxygen being not greater than 2.5×10¹⁵ atoms/cm² enabled the output to be improved when LEDs were fabricated.

### Embodiment 8

In the present embodiment, the effect of forming, in between the AlₓGa₍₁₋ₓ₎As substrate and the active layer, a buffer layer of controlled Al amount fraction was investigated.

### Sample 6

In Sample 6, at first a GaAs substrate was prepared (Step S1). Next, by a slow-cooling technique an AlₓGa₍₁₋ₓ₎As layer 11 was grown (Step S2). In Step S2, the layer was grown so as to contain one lamina in which the Al amount fraction x continually decreased heading in the growth direction. Meanwhile, the amount fraction x of Al in the major surface 11a of the AlₓGa₍₁₋ₓ₎As layer 11 was 0.25. And the carrier concentration in the AlₓGa₍₁₋ₓ₎As layer 11 was 5×10¹⁷ cm⁻³.

Next, a buffer layer 25 was formed by OMVPE onto the major surface 11a of the AlₓGa₍₁₋ₓ₎As layers 11. The amount fraction x of Al in the buffer layer 25 was constant at 0.15, while the thickness was 100 nm and the carrier concentration was 5×10¹⁷ cm⁻³.

An active layer 21 was then formed onto the buffer layer 25 by OMVPE. The amount fraction x of Al in the cladding layers (both n-type and p-type) within the active layer was constant at 0.35, while the thickness was 500 nm and the carrier concentration of the n-type cladding layer was 5×10¹⁷ cm⁻³.

Twenty of the epitaxial wafers 20d represented in FIG. 27 were thereby manufactured. With Sample 6 it was the case that the amount fraction (0.25) of Al in the major surface of the AlₓGa₍₁₋ₓ₎As substrate>the amount fraction (0.15) of Al in the buffer layer 25<the amount fraction (0.35) of Al in the active layer 21.

### Sample 7

The epitaxial wafer manufacturing method of Sample 7 was basically similar to that of Sample 6, while differing in terms of the buffer layer and the active layer. Specifically, the buffer layer 25 had an Al amount fraction x of 0, meaning that it was rendered a GaAs layer. Meanwhile, the thickness of the buffer layer 25 was made 10 nm. And inside the active layer 21, the amount fraction x of Al in the cladding layers was made 0.6. With Sample 7, it was the case that the amount fraction (0.25) of Al in the major surface of the AlₓGa₍₁₋ₓ₎As substrate>the amount fraction (0) of Al in the buffer layer 25<the amount fraction (0.6) of Al in the active layer 21.

### Sample 8

The epitaxial wafer manufacturing method of Sample 8 was basically similar to that of Sample 6, while differing in that no buffer layer was formed.

### Sample 9

The epitaxial wafer manufacturing method of Sample 9 was basically similar to that of Sample 7, while differing in that no buffer layer was formed.

### Measurement Method

Twenty of the epitaxial wafers of Samples 6 through 9 were utilized to fabricate twenty LEDs. In respect of each of the LEDs, the forward voltage V_{f}, which was the voltage during a forward measurement with I_{f}=20 mA, was then measured. Their maximum, minimum and average values are given in FIG. 40.

### Measurement Results

As indicated in FIG. 40, with Samples 6 and 7, in which a buffer layer 25 of low Al amount fraction was formed, compared with Samples 8 and 9, in which no buffer layer was formed, irregularities in the forward voltage V_{f} could be kept under control.

Meanwhile, with Sample 7, a GaAs layer was formed as a buffer layer 25; yet since the layer had a thin height, optical absorption could be minimized. Therefore, even in implementations in which a buffer layer of extraordinarily small Al amount fraction x was formed, thinning the height of the layer allowed the realization of epitaxial wafers in which influence exerted on the light output power was slight.

Particularly in Sample 9, since an active layer, in which the Al amount fraction x was large, was formed directly on AlₓGa₍₁₋ₓ₎As substrate, irregularities in V_{f} were significant. With Sample 7, however, in which the buffer layer 25 was created, even in implementations in which an active layer of large Al amount fraction was formed, irregularities in V_{f} could be kept under control.

From the foregoing, it could be confirmed that according to the present embodiment, forming, in between the AlₓGa₍₁₋ₓ₎As substrate and the active layer, a buffer layer of Al amount fraction controlled to be lower than that of the active layer allowed characteristics to be improved in the fabrication of LEDs.

### Embodiment 9

In the present embodiment, the effect of the amount fraction x of Al in the rear face 11b of the AlₓGa₍₁₋ₓ₎As layer 11 being 0.12 or greater was investigated.

Specifically, GaAs substrates were prepared (Step S1). Next, by a slow-cooling technique AlₓGa₍₁₋ₓ₎As layers 11 were grown (Step S2). In Step S2, the layers were grown so as to contain one lamina in which the Al amount fraction x continually decreased heading in the growth direction. And a plurality of AlₓGa₍₁₋ₓ₎As layers 11 was grown in a manner such that the amount fraction x of Al in the rear face 11b would differ. AlₓGa₍₁₋ₓ₎As substrates were thereby prepared.

Next an etching solution of ammonia:hydrogen peroxide=1:10 was prepared. This etching solution was utilized at room temperature to etch the GaAs substrates from the plurality of AlₓGa₍₁₋ₓ₎As substrates.

The result was that in the AlₓGa₍₁₋ₓ₎As layers 11, when the amount fraction of Al in the rear face 11b contacting the GaAs substrate was 0.12 or more, it was possible to remove the GaAs substrate by etching it for one minute at an etching rate of 3˜5 μm/minute (Step S3). Furthermore, in the AlₓGa₍₁₋ₓ₎As layers 11, when the amount fraction of Al in the rear face 11b contacting the GaAs substrate was 0.12 or more, the etching could be selectively halted along the rear face of the AlₓGa₍₁₋ₓ₎As layers.

From the foregoing it could be confirmed that according to the present embodiment, the amount fraction x of Al in the rear face 11b of the AlₓGa₍₁₋ₓ₎As layers 11 being 0.12 or greater made it possible to remove the GaAs substrates efficiently.

### Embodiment 10

In the present embodiment, the effectiveness with which an infrared LED of 900 nm or greater wavelength could be fabricated was examined.

In the present embodiment, an infrared LED was manufactured in the same way as with the infrared LED manufacturing method of Embodiment 4, while differing only in terms of the active layer 21. Specifically, in the present embodiment, an active layer 21 having 20 laminae of, respectively, well layers each having a thickness of 6 nm and consisting of In_{0.12}Ga_{0.88}As and barrier layers each having a thickness of 12 nm and consisting of GaAs_{0.9}P_{0.1} was grown.

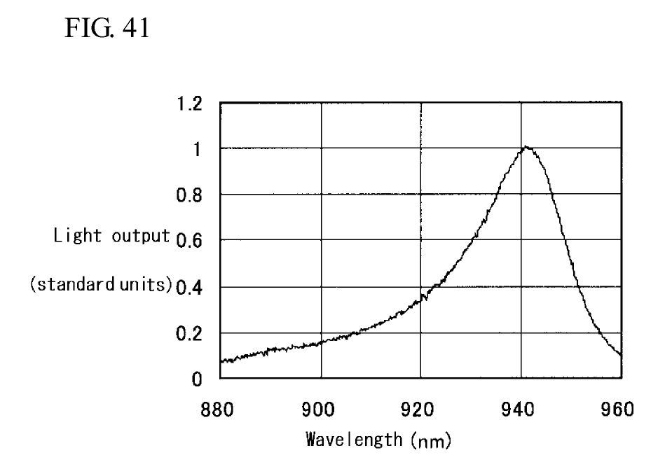

The emission spectrum for this infrared LED was characterized. The result is graphed in FIG. 41. As indicated in FIG. 41, it could be confirmed that the manufacture of an infrared LED of 940 nm emission wavelength was possible.

### Embodiment 11

In the present embodiment, the conditions for an epitaxial wafer to be utilized in an infrared LED of 900 nm or greater emission wavelength were examined.

### Present Invention Examples 1 through 4

The infrared LEDs of Present Invention Examples 1 through 4 were manufactured in the same way as with the infrared LED manufacturing method of Embodiment 10, while differing only in terms of the AlₓGa₍₁₋ₓ₎As layer 11 and the active layer 21. Specifically, the average amount fraction of Al in the AlₓGa₍₁₋ₓ₎As layers 11 was made to be as set forth in Table III below.

The Al amount fraction in the major surface and in the rear face of the AlₓGa₍₁₋ₓ₎As layers 11 was, to cite single instances in the order (rear face, major surface): for 0.05, (0.10, 0.01); for 0.15, (0.25, 0.05); for 0.25, (0.35, 0.15); and for 0.35, (0.40, 0.30). The average Al amount fraction and the amount fraction in the (rear face, major surface) are, however, adjustable at will. Here, the amount fraction of Al monotonically decreased heading from the rear face to the major surface of the AlₓGa₍₁₋ₓ₎As layers 11. And for the active layer 21 in these cases, an active layer 21 having 5 laminae of, respectively, well layers each consisting of InGaAs and barrier layers each consisting of GaAs was grown. The infrared LEDs had an emission wavelength of 890 nm.

### Present Invention Examples 5 through 8

The infrared LEDs of Present Invention Examples 5 through 8 were manufactured in the same way as with the infrared LED manufacturing method of Present Invention Examples 1 through 4, while differing in that the emission wavelength was 940 nm.

### Comparative Examples 1 and 2

The infrared LEDs of Comparative Examples 1 and 2 were manufactured similarly as with the infrared LEDs of Present Invention Examples 1 through 4 and Present Invention Examples 5 through 8, respectively, but differed in not being furnished with an AlₓGa₍₁₋ₓ₎As layer 11. That is, an AlₓGa₍₁₋ₓ₎As layer 11 was not formed, nor was the GaAs substrate removed.

### Measurement Method

Lattice relaxation with regard to the infrared LEDs of Present Invention Examples 1 through 8 and Comparative Examples 1 and 2 was determined. The lattice relaxation was characterized by photoluminescence spectroscopy, x-ray diffraction, and visual inspection of the surface. When the lattice-relaxed epitaxial wafers were fabricated into infrared LEDs, they were verified as such by dark lines. Furthermore, the light output power of the infrared LEDs of Present Invention Examples 1 through 8 and Comparative Examples 1 and 2 was measured in the same way as in Embodiment 3. The results are set forth in Table III below.

TABLE III

| | Substrate | | Active layer | | | | Light |
|---|---|---|---|---|---|---|---|
| | | Al amt. | | Number | Lattice | Emission | output |
| | Material | fract. | Composition | laminae | relax. | wvling. | power |
| Pres. Inv. Ex. 1 | AlGaAs | 0.05 | InGaAs/GaAs | 5 | Absent | 890 nm | 5 mW |
| Pres. Inv. Ex. 2 | AlGaAs | 0.15 | InGaAs/GaAs | 5 | Absent | 890 nm | 6 mW |
| Pres. Inv. Ex. 3 | AlGaAs | 0.25 | InGaAs/GaAs | 5 | Absent | 890 nm | 6 mW |
| Pres. Inv. Ex. 4 | AlGaAs | 0.35 | InGaAs/GaAs | 5 | Absent | 890 nm | 6 mW |
| Comp. Ex. 1 | GaAs | — | InGaAs/GaAs | 5 | Absent | 890 nm | 1.5 mW |
| Pres. Inv. Ex. 5 | AlGaAs | 0.05 | InGaAs/GaAs | 5 | Pres. | 940 nm | 2 mW |
| Pres. Inv. Ex. 6 | AlGaAs | 0.15 | InGaAs/GaAs | 5 | Pres. | 940 nm | 3 mW |
| Pres. Inv. Ex. 7 | AlGaAs | 0.25 | InGaAs/GaAs | 5 | Pres. | 940 nm | 3.5 mW |
| Pres. Inv. Ex. 8 | AlGaAs | 0.35 | InGaAs/GaAs | 5 | Pres. | 940 nm | 3.5 mW |
| Comp. Ex. 2 | GaAs | — | InGaAs/GaAs | 5 | Absent | 940 nm | 1.5 mW |

As indicated in Table III, in the infrared LEDs whose emission wavelength was 890 nm, there was no lattice relaxation (lattice misalignment), regardless of whether the substrate was a GaAs substrate or an AlₓGa₍₁₋ₓ₎As layer. Likewise, in the infrared LED of Comparative Example 2, made from a GaAs substrate alone, there was no lattice relaxation, despite the emission wavelength being 940 nm. In the infrared LEDs of Present Invention Examples 5 through 8, however, which were furnished with an AlₓGa₍₁₋ₓ₎As layer 11 as an AlₓGa₍₁₋ₓ₎As substrate and which had an emission wavelength of 940 nm, there was lattice relaxation. Thus, with infrared LEDs furnished with an AlₓGa₍₁₋ₓ₎As layer 11 as an AlₓGa₍₁₋ₓ₎As substrate, whereas the output power of the infrared LEDs in which there was no lattice relaxation was 5 mW to 6 mW, the output power of the infrared LEDs in which there was lattice relaxation was a low 2 to 3.5 mW, wherein it was understood that inconsistencies within the surface of the same wafer are considerable. More particularly, the measurement inconsistencies were in wafers having a 2- to 4-inch φ wafer diameter.

From these facts it was understood that technology that can be applied on GaAs substrates cannot be applied to epitaxial wafers that are utilized in infrared LEDs whose emission wavelength is 900 nm or greater.

Therein, the present inventors devoted research, as discussed below, to investigating the conditions whereby lattice relaxation is curbed in epitaxial wafers that are utilized in infrared LEDs whose emission wavelength is 900 nm or greater.

Specifically, in the following way, infrared LEDs of Present Invention Examples 9 through 24 and Comparative Examples 3 through 6, in which the emission wavelength was 940 nm, were manufactured.

### Present Invention Examples 9 through 12

The infrared LEDs of Present Invention Examples 9 through 12 basically were manufactured in the same way as with the infrared LEDs of Present Invention Examples 5 through 8, while differing in that the number of well layers and barrier layers, respectively, each was made three laminae. The In amount fraction in the well layers was 0.12.

### Present Invention Examples 13 through 16

The infrared LEDs of Present Invention Examples 13 through 16 basically were manufactured in the same way as with the infrared LEDs of Present Invention Examples 5 through 8, while differing in having the barrier layers be GaAsP, and in making the number of well layers and barrier layers each be three laminae. The P amount fraction in the barrier layers was 0.10.

### Present Invention Examples 17 through 20

The infrared LEDs of Present Invention Examples 17 through 20 basically were manufactured in the same way as with the infrared LEDs of Present Invention Examples 13 through 16, while differing in that the number of well layers and barrier layers each was made be ten laminae.

### Present Invention Examples 21 through 24

The infrared LEDs of Present Invention Examples 21 through 24 basically were manufactured in the same way as with the infrared LEDs of Present Invention Examples 5 through 8, while differing in having the barrier layers be AlGaAsP, and in making the number of well layers and of barrier layers each be twenty laminae. The P amount fraction in the barrier layers was 0.10.

### Comparative Examples 3 through 6

The infrared LEDs of Comparative Examples 3 through 6 basically were manufactured in the same way as with the infrared LEDs of, respectively, Present Invention Examples 9 through 12, Present Invention Examples 13 through 16, Present Invention Examples 17 through 20, and Present Invention Examples 21 through 24, while differing in that a GaAs substrate not furnished with an AlₓGa₍₁₋ₓ₎As layer as an AlₓGa₍₁₋ₓ₎As substrate was employed.

### Measurement Method

In the same manner as with the methods explained above, the lattice relaxation and light output power were determined. The results are set forth in Table IV below.

TABLE IV

| | Substrate | | Active layer | | | Light |
|---|---|---|---|---|---|---|
| | | Al amt. | | Number | Lattice | output |
| | Material | fract. | Composition | laminae | relax. | power |
| Pres. Inv. Ex. 9 | AlGaAs | 0.05 | InGaAs/GaAs | 3 | Absent | 6 mW |
| Pres. Inv. Ex. 10 | AlGaAs | 0.15 | InGaAs/GaAs | 3 | Absent | 6 mW |
| Pres. Inv. Ex. 11 | AlGaAs | 0.25 | InGaAs/GaAs | 3 | Absent | 6 mW |
| Pres. Inv. Ex. 12 | AlGaAs | 0.35 | InGaAs/GaAs | 3 | Absent | 6 mW |
| Comp. Ex. 3 | GaAs | — | InGaAs/GaAs | 3 | Absent | 1.5 mW |
| Pres. Inv. Ex. 13 | AlGaAs | 0.05 | InGaAs/GaAsP | 3 | Absent | 6 mW |
| Pres. Inv. Ex. 14 | AlGaAs | 0.15 | InGaAs/GaAsP | 3 | Absent | 6 mW |
| Pres. Inv. Ex. 15 | AlGaAs | 0.25 | InGaAs/GaAsP | 3 | Absent | 6 mW |
| Pres. Inv. Ex. 16 | AlGaAs | 0.35 | InGaAs/GaAsP | 3 | Absent | 6 mW |
| Comp. Ex. 4 | GaAs | — | InGaAs/GaAsP | 3 | Absent | 1.5 mW |
| Pres. Inv. Ex. 17 | AlGaAs | 0.05 | InGaAs/GaAsP | 10 | Absent | 6 mW |
| Pres. Inv. Ex. 18 | AlGaAs | 0.15 | InGaAs/GaAsP | 10 | Absent | 6 mW |
| Pres. Inv. Ex. 19 | AlGaAs | 0.25 | InGaAs/GaAsP | 10 | Absent | 6 mW |
| Pres. Inv. Ex. 20 | AlGaAs | 0.35 | InGaAs/GaAsP | 10 | Absent | 6 mW |
| Comp. Ex. 5 | GaAs | — | InGaAs/GaAsP | 10 | Absent | 1.5 mW |
| Pres. Inv. Ex. 21 | AlGaAs | 0.05 | InGaAs/AlGaAsP | 20 | Absent | 6 mW |
| Pres. Inv. Ex. 22 | AlGaAs | 0.15 | InGaAs/AlGaAsP | 20 | Absent | 6 mW |
| Pres. Inv. Ex. 23 | AlGaAs | 0.25 | InGaAs/AlGaAsP | 20 | Absent | 6 mW |
| Pres. Inv. Ex. 24 | AlGaAs | 0.35 | InGaAs/AlGaAsP | 20 | Absent | 6 mW |
| Comp. Ex. 6 | GaAs | — | InGaAs/AlGaAsP | 20 | Absent | 1.5 mW |

### Measurement Results

As indicated in Table IV, with Present Invention Examples 9 through 12, which included InGaAs wherein the well layers inside the active layer 21 contained In, and whose number of well layers was four laminae or fewer, lattice relaxation did not occur.

Likewise, with Present Invention Examples 13 through 24, which included either GaAsP or AlGaAsP wherein the barrier layers inside the active layer contained P, and whose number of barrier layers was three laminae or more, lattice relaxation did not occur.

From the foregoing, according to the present embodiments, it was discovered that in epitaxial wafers utilized in infrared LEDs whose emission wavelength is 900 nm or greater, lattice misalignment can be controlled to a minimum in instances where the well layers inside the active layer include a material containing In, and the number of well layers is four or fewer laminae, as well as in instances where the barrier layers inside the active layer include a material containing P and the number of barrier layers is three or more laminae.

The presently disclosed embodying modes and embodiment examples should in all respects be considered to be illustrative and not limiting. The scope of the present invention is set forth not by the embodying modes described in the foregoing, but by the scope of the patent claims, and is intended to include meanings equivalent to the scope of the patent claims and all modifications within the scope.

### REFERENCE SIGNS LIST

10a, 10b: AlₓGa₍₁₋ₓ₎As substrate; 11: AlₓGa₍₁₋ₓ₎As layer; 11a, 13a: major surface; 11b, 13b, 20c2, 21c: rear face; 13: GaAs substrate; 20a, 20b, 20c, 20d, 40, 50: epitaxial wafer; 20c1: front side; 21: active layer; 21a: well layers; 21b: barrier layers; 23: contact layer; 25: buffer layer; 30a, 30b, 30c, 30d: LEDs; 31, 32: electrodes; 33: stem; 41, 44: cladding layers; 42, 43: undoped guide layers

1. An AlₓGa₍₁₋ₓ₎As substrate furnished with an AlₓGa₍₁₋ₓ₎As layer (0≦x≦1) having a major surface and, on the reverse side from the major surface, a rear face; the AlₓGa₍₁₋ₓ₎As substrate characterized in that:
in said AlₓGa₍₁₋ₓ₎As layer, the amount fraction x of Al in the rear face is greater than the amount fraction x of Al in the major surface.

2. The AlₓGa₍₁₋ₓ₎As substrate set forth in claim 1, wherein:
the AlₓGa₍₁₋ₓ₎As layer contains a plurality of laminae; and
the amount fraction x of Al in each of the plural laminae monotonically decreases heading from the plane of the layer's rear-face side to the plane of its major-surface side.

3. The AlₓGa₍₁₋ₓ₎As substrate set forth in claim 1, wherein: letting ΔAl be the difference in amount fraction x of Al in two different points thickness-wise through said AlₓGa₍₁₋ₓ₎As layer, and letting Δt be the difference in thickness (μm) between the two points, then ΔAl/Δt is greater than 0/μm.

4. The AlₓGa₍₁₋ₓ₎As substrate set forth in claim 3, wherein ΔAl/Δt is not greater than 6×10⁻²/μm.

5. The AlₓGa₍₁₋ₓ₎As substrate set forth in claim 1, wherein the amount fraction x of Al in the rear face of said AlₓGa₍₁₋ₓ₎As layer is not less than 0.12.

6. The AlₓGa₍₁₋ₓ₎As substrate set forth in claim 1, further furnished with a GaAs substrate contacting the rear face of said AlₓGa₍₁₋ₓ₎As layer.

7. An epitaxial wafer for infrared LEDs, furnished with:
the AlₓGa₍₁₋ₓ₎As substrate set forth in claim 1; and
an epitaxial layer formed onto the major surface of said AlₓGa₍₁₋ₓ₎As layer, and including an active layer.

8. The infrared-LED epitaxial wafer set forth in claim 7, wherein the amount fraction x of Al in the epitaxial layer plane of contact with said AlₓGa₍₁₋ₓ₎As layer is greater than the amount fraction x of Al in the AlₓGa₍₁₋ₓ₎As layer plane of contact with said epitaxial layer.

9. The infrared-LED epitaxial wafer set forth in claim 8, wherein:
said epitaxial layer further includes a buffer layer having a plane of contact with said AlₓGa₍₁₋ₓ₎As layer; and
the amount fraction x of Al in said buffer layer is lower than the amount fraction x of Al in said active layer.

10. The infrared-LED epitaxial wafer set forth in claim 7, wherein:
said epitaxial layer further includes a buffer layer having a plane of contact with the AlₓGa₍₁₋ₓ₎As layer; and
the amount fraction x of Al in said buffer layer is lower than the amount fraction x of Al in the AlₓGa₍₁₋ₓ₎As layer plane of contact with said epitaxial layer, and lower than the amount fraction x of Al in said active layer.

11. The infrared-LED epitaxial wafer set forth in claim 7, wherein the peak concentration of oxygen at the interface between said AlₓGa₍₁₋ₓ₎As layer and said epitaxial layer is not greater than 5×10²⁰ atoms/cm³.

12. The infrared-LED epitaxial wafer set forth in claim 7, wherein the planar density of oxygen at the interface between said AlₓGa₍₁₋ₓ₎As layer and said epitaxial layer is not greater than 2.5×10¹⁵ atoms/cm².

13. An infrared LED furnished with:
the AlₓGa₍₁₋ₓ₎As substrate set forth in claim 1;
an epitaxial layer formed onto the major surface of said AlₓGa₍₁₋ₓ₎As layer, and including an active layer;
a first electrode formed superficially on said epitaxial layer; and
a second electrode formed on the rear face of said AlₓGa₍₁₋ₓ₎As layer.

14. An infrared LED furnished with:
the AlₓGa₍₁₋ₓ₎As substrate set forth in claim 6;
an epitaxial layer formed onto the major surface of said AlₓGa₍₁₋ₓ₎As layer, and including an active layer;
a first electrode formed superficially on said epitaxial layer; and
a second electrode formed on said GaAs substrate, on its rear face.

15. An AlₓGa₍₁₋ₓ₎As substrate manufacturing method provided with:
a step of preparing a GaAs substrate; and
a step of growing, by LPE, onto the GaAs substrate an AlₓGa₍₁₋ₓ₎As layer (0≦x≦1) having a major surface and, on the reverse side from the major surface, a rear face; characterized in that:
in said step of growing an AlₓGa₍₁₋ₓ₎As layer, the AlₓGa₍₁₋ₓ₎As layer is grown with the amount fraction x of Al in the rear face being greater than the amount fraction x of Al in the major surface.

16. The AlₓGa₍₁₋ₓ₎As substrate manufacturing method set forth in claim 15, wherein in said step of growing an AlₓGa₍₁₋ₓ₎As layer, the AlₓGa₍₁₋ₓ₎As layer is grown containing a plurality of laminae in which the amount fraction x of Al monotonically decreases heading from the plane of the layer's rear-face side to the plane of its major-surface side.

17. The AlₓGa₍₁₋ₓ₎As substrate manufacturing method set forth in claim 15, wherein letting ΔAl be the difference in amount fraction x of Al in two different points thickness-wise through the AlₓGa₍₁₋ₓ₎As layer, and letting Δt be the difference in thickness (μm) between the two points, then ΔAl/Δt is greater than 0/μm.

18. The AlₓGa₍₁₋ₓ₎As substrate manufacturing method set forth in claim 17, wherein ΔAl/Δt is not greater than 6×10⁻²/μm.

19. The AlₓGa₍₁₋ₓ₎As substrate manufacturing method set forth in claim 15, wherein the amount fraction x of Al in the rear face of the AlₓGa₍₁₋ₓ₎As layer is not less than 0.12.

20. The AlₓGa₍₁₋ₓ₎As substrate manufacturing method set forth in claim 15, further provided with a step of removing the GaAs substrate.

21. A method of manufacturing an epitaxial wafer for infrared LEDs, provided with:
a step of manufacturing an AlₓGa₍₁₋ₓ₎As substrate by the AlₓGa₍₁₋ₓ₎As substrate manufacturing method set forth in claim 15; and
a step of forming onto the major surface of the AlₓGa₍₁₋ₓ₎As layer, by at least either OMVPE or MBE, an epitaxial layer containing an active layer.

22. The infrared-LED epitaxial wafer manufacturing method set forth in claim 21, wherein the amount fraction x of Al in the epitaxial layer plane of contact with the AlₓGa₍₁₋ₓ₎As layer is greater than the amount fraction x of Al in the AlₓGa₍₁₋ₓ₎As layer plane of contact with the epitaxial layer.

23. The infrared-LED epitaxial wafer manufacturing method set forth in claim 22, wherein:
in said step of forming an epitaxial layer, the epitaxial layer is formed further including a buffer layer having a plane of contact with the AlₓGa₍₁₋ₓ₎As layer; and
the amount fraction x of Al in the buffer layer is lower than the amount fraction x of Al in the active layer.

24. The infrared-LED epitaxial wafer manufacturing method set forth in claim 21, wherein:
in said step of forming an epitaxial layer, the epitaxial layer is formed further including a buffer layer having a plane of contact with the AlₓGa₍₁₋ₓ₎As layer; and
the amount fraction x of Al in the buffer layer is lower than the amount fraction x of Al in the AlₓGa₍₁₋ₓ₎As layer plane of contact with the epitaxial layer, and lower than the amount fraction x of Al in the active layer.

25. The infrared-LED epitaxial wafer manufacturing method set forth in claim 21, wherein the peak concentration of oxygen at the interface between the AlₓGa₍₁₋ₓ₎As layer and the epitaxial layer is not greater than 5×10²⁰ atoms/cm³.

26. The infrared-LED epitaxial wafer manufacturing method set forth in claim 21, wherein the planar density of oxygen at the interface between said AlₓGa₍₁₋ₓ₎As layer and said epitaxial layer is not greater than 2.5×10¹⁵ atoms/cm².

27. A method of manufacturing an infrared LED, provided with:
a step of manufacturing an AlₓGa₍₁₋ₓ₎As substrate by the AlₓGa₍₁₋ₓ₎As substrate manufacturing method set forth in claim 15;
a step of forming onto the major surface of the AlₓGa₍₁₋ₓ₎As layer, by either OMVPE or MBE, an epitaxial layer containing an active layer, to yield an epitaxial wafer;
a step of forming a first electrode superficially on the epitaxial wafer; and
a step of forming a second electrode the GaAs substrate, on its rear face.

28. A method of manufacturing an infrared LED, provided with:
a step of manufacturing an AlₓGa₍₁₋ₓ₎As substrate by the AlₓGa₍₁₋ₓ₎As substrate manufacturing method set forth in claim 20;
a step of forming onto the major surface of the AlₓGa₍₁₋ₓ₎As layer, by either OMVPE or MBE, an epitaxial layer containing an active layer, to yield an epitaxial wafer;
a step of forming a first electrode superficially on the epitaxial wafer; and
a step of forming a second electrode on the rear face of the AlₓGa₍₁₋ₓ₎As layer.
